(19) United States
(12) Patent Application Publication
(10) Pub. No.: US 2024/0224810 A1
(43) Pub. Date: Jul. 4, 2024

(54) PIEZOELECTRIC DEVICE AND APPARATUS INCLUDING THE SAME

(71) Applicant: LG Display Co., Ltd., Seoul (KR)

(72) Inventors: YongWoo LEE, Paju-si (KR); JounHo LEE, Paju-si (KR); Sooyoun KIM, Paju-si (KR); HwaYoul LEE, Paju-si (KR); Uihyeon JEONG, Paju-si (KR)

(73) Assignee: LG Display Co., Ltd., Seoul (KR)

(21) Appl. No.: 18/381,076

(22) Filed: Oct. 17, 2023

(30) Foreign Application Priority Data
Dec. 30, 2022 (KR) 10-2022-0191219

(51) Int. Cl. H10N 30/87; H10N 30/20

(52) U.S. Cl. CPC H10N 30/877; H10N 30/20

(57) ABSTRACT

Discussed is a piezoelectric device that can include a piezoelectric device layer, a first electrode layer at a first surface of the piezoelectric device layer, and a second electrode layer at a second surface different from the first surface of the piezoelectric device layer. The piezoelectric device layer includes a first vibration portion and a second vibration portion overlapping each other in a thickness direction of the piezoelectric device layer and having different characteristics.

### CROSS-REFERENCE TO RELATED APPLICATIONS

This application claims priority to Korean Patent Application No. 10-2022-0191219 filed in the Republic of Korea on Dec. 30, 2022, the entire contents of which is hereby expressly incorporated by reference into the present application.

### BACKGROUND

### Technical Field

The present disclosure relates to a piezoelectric device and an apparatus including the same.

### Description of the Related Art

Piezoelectric materials are being widely used as materials of parts for devices such as ultrasound vibrators, electromechanical transducers, and actuators used in various and extensive field of ultrasound devices, video devices, sound devices, communication devices, and sensors since piezoelectric materials can be configured to produce sounds.

Pb(Zr, Ti)O₃ (PZT)-based materials have a strong piezoelectric characteristic, and thus, are used as a piezoelectric material in wide variety of applications. However, lead (Pb) is a material having strong toxicity and has high volatility in a sintering process, and due to this, causes serious health issues and environmental pollution.

Therefore, because a PZT piezoelectric material being used as the most prevalent piezoelectric materials causes a health and an environmental pollution problem, it is desirable to develop a Pb-free piezoelectric material that has a strong piezoelectric characteristic to avoid lowered performance.

### SUMMARY OF THE DISCLOSURE

The inventors have performed various research and experiments for providing a piezoelectric device and an apparatus including the same, in which a piezoelectric characteristic and reliability can be improved without including lead (Pb). Based on the various research and experiments, the inventors have invented a piezoelectric device including a Pb-free piezoelectric material and an apparatus including the piezoelectric device.

An aspect of the present disclosure is directed to providing a piezoelectric device and an apparatus including the same, in which a piezoelectric characteristic and reliability are improved without including Pb.

Another aspect of the present disclosure is directed to providing a piezoelectric device and an apparatus including the same, in which the piezoelectric characteristic and reliability of a piezoelectric device including a Pb-free piezoelectric material are enhanced.

Another aspect of the present disclosure is directed to providing a piezoelectric device and an apparatus including the same, in which the piezoelectric characteristic and reliability of a piezoelectric device based on a multilayer structure combination of Pb-free piezoelectric materials having different characteristics are enhanced.

The objects of the present disclosure are not limited to the aforesaid, but other objects not described herein will be clearly understood by those skilled in the art from descriptions below.

A piezoelectric device according to an embodiment of the present disclosure can include a piezoelectric device layer, a first electrode layer at a first surface of the piezoelectric device layer, and a second electrode layer at a second surface different from the first surface of the piezoelectric device layer. The piezoelectric device layer can include a first vibration portion and a second vibration portion which overlap each other in a thickness direction of the piezoelectric device layer and have different characteristics.

An apparatus according to an embodiment of the present disclosure can include a vibration member and at least one vibration apparatus configured to vibrate the vibration member, wherein the at least one vibration apparatus can include a piezoelectric device layer, a first electrode layer at a first surface of the piezoelectric device layer, and a second electrode layer at a second surface different from the first surface of the piezoelectric device layer. The piezoelectric device layer can include a first vibration portion and a second vibration portion which overlap each other in a thickness direction of the piezoelectric device layer and have different characteristics.

According to an embodiment of the present disclosure, a piezoelectric device and an apparatus including the same, in which a piezoelectric characteristic and reliability are improved without including Pb, can be provided.

According to an embodiment of the present disclosure, a piezoelectric device and an apparatus including the same, in which the piezoelectric characteristic and reliability of a piezoelectric device including a Pb-free piezoelectric material are enhanced, can be provided.

According to an embodiment of the present disclosure, a piezoelectric device and an apparatus including the same, in which the piezoelectric characteristic and reliability of a piezoelectric device based on a multilayer structure combination of Pb-free piezoelectric materials having different characteristics are enhanced, can be provided.

A piezoelectric device and an apparatus including the same according to an embodiment of the present disclosure can include a Pb-free piezoelectric material, and thus, can realize an effect of preventing the toxicity of Pb and environmental pollution caused by a harmful material occurring in a sintering process, an effect of decreasing a production harmful/restrictive material, an effect of providing an environment-friendly product, and an effect of replacing a harmful material.

In addition to the effects of the present disclosure as mentioned above, additional objects of the present disclosure will be clearly understood by those skilled in the art from the following description of the present disclosure.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure and together with the description serve to explain the principle of the disclosure.

FIG. 1 illustrates a piezoelectric device according to an embodiment of the present disclosure.

FIG. 2 illustrates another structure of a piezoelectric device according to an embodiment of the present disclosure.

FIG. 3 illustrates another structure of a piezoelectric device according to an embodiment of the present disclosure.

FIG. 4 illustrates another structure of a piezoelectric device according to an embodiment of the present disclosure.

FIG. 5 illustrates another structure of a piezoelectric device according to an embodiment of the present disclosure.

FIG. 6 illustrates a piezoelectric device according to another embodiment of the present disclosure.

FIG. 7 illustrates another structure of a piezoelectric device according to another embodiment of the present disclosure.

FIG. 8 illustrates a piezoelectric device according to another embodiment of the present disclosure.

FIG. 9 illustrates another structure of a piezoelectric device according to another embodiment of the present disclosure.

FIG. 10 illustrates an apparatus according to an embodiment of the present disclosure.

FIG. 11 is a cross-sectional view taken along line I-I′ of FIG. 10 according to an embodiment of the present disclosure.

FIG. 12 illustrates a vibration apparatus of FIG. 11 according to an embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction of thereof can be exaggerated for clarity, illustration, and convenience.

### DETAILED DESCRIPTION OF THE EMBODIMENTS

Reference is now made in detail to embodiments of the present disclosure, examples of which can be illustrated in the accompanying drawings. In the following description, when a detailed description of well-known functions or configurations can unnecessarily obscure aspects of the present disclosure, the detailed description thereof can be omitted for brevity. The progression of processing steps and/or operations described is an example; however, the sequence of steps and/or operations is not limited to that set forth herein and can be changed, with the exception of steps and/or operations necessarily occurring in a particular order.

Advantages and features of the present disclosure, and implementation methods thereof, are clarified through the embodiments described with reference to the accompanying drawings. The present disclosure can, however, be embodied in different forms and should not be construed as limited to the embodiments set forth herein. Rather, these embodiments are examples and are provided so that this disclosure can be thorough and complete, to assist those skilled in the art to understand the inventive concepts without limiting the protected scope of the present disclosure.

The shapes, sizes, areas, ratios, angles, numbers, and the like disclosed in the drawings for describing embodiments of the present disclosure are merely an example, and thus, the present disclosure is not limited to the illustrated details. Like reference numerals refer to like elements throughout.

When the term “comprise,” “have,” “include,” “contain,” “constitute,” “made up of,” “formed of,” or the like is used, one or more other elements can be added unless a term such as “only” or the like is used. The terms used in the present disclosure are merely used in order to describe particular embodiments by way of example, and are not intended to limit the scope of the present disclosure. The terms of a singular form can include plural forms unless the context clearly indicates otherwise. The word “exemplary” is used to mean serving as an example or illustration. Embodiments are example embodiments. Aspects are example aspects. Any implementation described herein as an “example” is not necessarily to be construed as preferred or advantageous over other implementations.

In one or more aspects, an element, feature, or corresponding information (e.g., a level, range, dimension, size, or the like) is construed as including an error or tolerance range even where no explicit description of such an error or tolerance range is provided. An error or tolerance range can be caused by various factors (e.g., process factors, internal or external impact, noise, or the like). Further, the term “can” encompasses all the meanings of the term “can.”

In describing a positional relationship, where the positional relationship between two parts is described, for example, using “on,” “over,” “under,” “above,” “below,” “beneath,” “near,” “close to,” “adjacent to,” “beside,” “next to,” or the like, one or more parts can be located between two other parts unless a more limiting term, such as “immediate(ly),” “direct(ly),” or “close(ly),” is used. For example, when a structure is described as being positioned “on,” “over,” “under,” “above,” “below,” “beneath,” “near,” “close to,” “adjacent to,” “beside,” or “next to” another structure, this description should be construed as including a case in which the structures contact each other as well as a case in which one or more additional structures are disposed or interposed therebetween. Furthermore, the terms “front,” “rear,” “back,” “left,” “right,” “top,” “bottom,” “downward,” “upward,” “upper,” “lower,” “up,” “down,” “column,” “row,” “vertical,” “horizontal,” and the like refer to an arbitrary frame of reference.

In describing a temporal relationship, when the temporal order is described as “after,” “subsequent,” “next,” “before,” “preceding,” “prior to,” or the like a case which is not consecutive or not sequential can be included, unless a more limiting term, such as “just,” “immediate(ly),” or “direct(ly)” is used.

It will be understood that, although the term “first”, “second,” or the like can be used herein to describe various elements, these elements should not be limited by these terms. These terms are only used to partition one element from another. For example, a first element could be a second element, and, similarly, a second element could be a first element, without departing from the scope of the present disclosure. Furthermore, the first element, the second element, and the like can be arbitrarily named according to the convenience of those skilled in the art without departing from the scope of the present disclosure. The terms “first,” “second,” and the like can be used to distinguish components from each other, but the functions or structures of the components are not limited by ordinal numbers or component names in front of the components.

In describing elements of the present disclosure, the terms “first,” “second,” “A,” “B,” “(a),” “(b),” or the like can be used. These terms are intended to identify the corresponding element(s) from the other element(s), and these are not used to define the essence, basis, order, or number of the elements.

For the expression that an element or a layer is “connected,” “coupled,” “attached,” or “adhered” to another element or layer the element or layer can not only be directly connected, coupled, attached, or adhered to another element or layer, but also be indirectly connected, coupled, attached, or adhered to another element or layer with one or more intervening elements or layers disposed or interposed between the elements or layers, unless otherwise specified.

For the expression that an element or layer “contacts,” “overlaps,” or the like with another element or layer, the element or layer can not only directly contact, overlap, or the like with another element or layer, but also indirectly contact, overlap, or the like with another element or layer with one or more intervening elements or layers disposed or interposed between the elements or layers, unless otherwise specified.

The terms such as a “line” or “direction” should not be interpreted only based on a geometrical relationship in which the respective lines or directions are parallel or perpendicular to each other, and can be meant as lines or directions having wider directivities within the range within which the components of the present disclosure can operate functionally.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as only one of the first item, the second item, or the third item.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C. Furthermore, an expression “element A/element B” can be understood as element A and/or element B.

In one or more aspects, the terms “between” and “among” can be used interchangeably simply for convenience unless stated otherwise. For example, an expression “between a plurality of elements” can be understood as among a plurality of elements. In another example, an expression “among a plurality of elements” can be understood as between a plurality of elements. In one or more examples, the number of elements can be two. In one or more examples, the number of elements can be more than two.

In one or more aspects, the phrases “each other” and “one another” can be used interchangeably simply for convenience unless stated otherwise. For example, an expression “different from each other” can be understood as being different from one another. In another example, an expression “different from one another” can be understood as being different from each other. In one or more examples, the number of elements involved in the foregoing expression can be two. In one or more examples, the number of elements involved in the foregoing expression can be more than two.

In one or more aspects, the phrases “one or more among” and “one or more of” can be used interchangeably simply for convenience unless stated otherwise.

Features of various embodiments of the present disclosure can be partially or wholly coupled to or combined with each other, and can be variously inter-operated, linked or driven together. The embodiments of the present disclosure can be carried out independently from each other, or can be carried out together in a co-dependent or related relationship. In one or more aspects, the components of each apparatus according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

In the following description, various example embodiments of the present disclosure are described in detail with reference to the accompanying drawings. With respect to reference numerals to elements of each of the drawings, the same elements can be illustrated in other drawings, and like reference numerals can refer to like elements unless stated otherwise. In addition, for convenience of description, a scale, dimension, size, and thickness of each of the elements illustrated in the accompanying drawings can be different from an actual scale, dimension, size, and thickness, and thus, embodiments of the present disclosure are not limited to a scale, dimension, size, and thickness illustrated in the drawings.

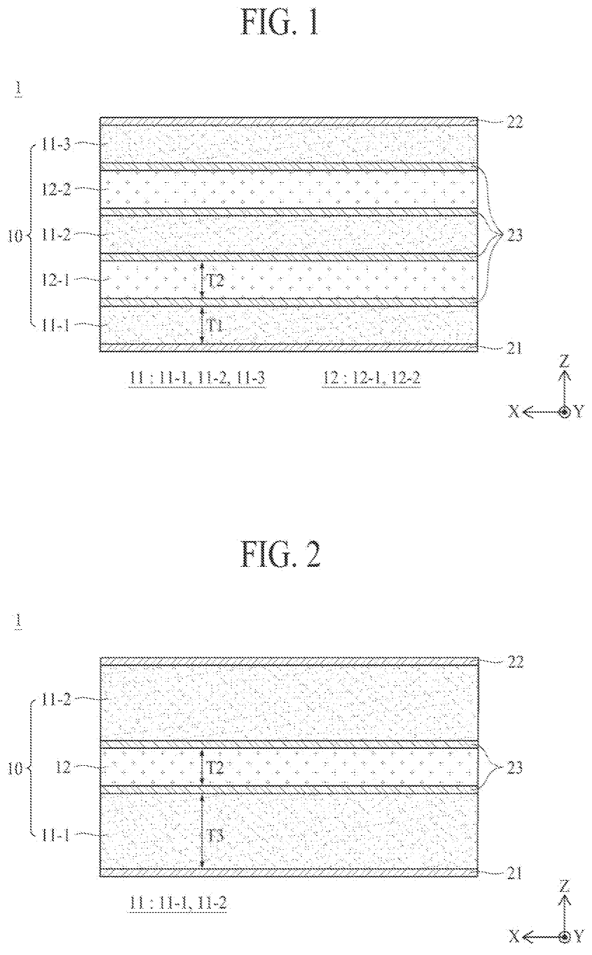

FIG. 1 illustrates a piezoelectric device 1 according to an embodiment of the present disclosure. All components of each piezoelectric device according to all embodiments of the present disclosure are operatively coupled and configured.

Referring to FIG. 1, the piezoelectric device 1 according to an embodiment of the present disclosure can include a piezoelectric device layer 10, a first electrode layer 21, a second electrode layer 22, and one or more middle electrode layers 23.

The piezoelectric device layer 10 can be configured between the first electrode layer 21 and the second electrode layer 22. The piezoelectric device layer 10 can include a first vibration portion 11 and a second vibration portion 12 having different characteristics. For example, the first vibration portion 11 and the second vibration portion 12 can be configured to overlap each other in a thickness direction Z of the piezoelectric device layer 10. The piezoelectric device layer 10 can include a circular plate shape, a polygonal plate shape, an oval shape, or a ring shape, but embodiments of the present disclosure are not limited thereto. For example, each of the first vibration portion 11 and the second vibration portion 12 each included in the piezoelectric device layer 10 can include a circular plate shape, a polygonal plate shape, an oval shape, or a ring shape, but embodiments of the present disclosure are not limited thereto.

Each of the first vibration portion 11 and the second vibration portion 12 of the piezoelectric device layer 10 can include a piezoelectric material having a piezoelectric effect (or a piezoelectric characteristic). For example, each of the first vibration portion 11 and the second vibration portion 12 can be an inorganic layer, an inorganic material layer, a piezoelectric material layer, an electro active layer, a piezoelectric portion, an inorganic portion, an inorganic material portion, a piezoelectric material portion, or an electro active portion, but embodiments of the present disclosure are not limited thereto.

The first vibration portion 11 and the second vibration portion 12 can include a ceramic-based material capable of implementing a relatively strong vibration, or can include piezoelectric ceramic having a perovskite crystalline structure. The perovskite crystalline structure can have a piezoelectric and/or inverse piezoelectric effect and can be a plate-shaped structure having an orientation.

According to an embodiment of the present disclosure, each of the first vibration portion 11 and the second vibration portion 12 can include a lead zirconate titanate (PZT)-based piezoelectric material including Pb, zirconium (Zr), and titanium (Ti) each having a high piezoelectric characteristic, but is not limited thereto and can include a Pb-free piezoelectric material so as to prevent the toxicity of Pb and environmental pollution caused by a harmful material occurring in a sintering process. For example, the Pb-free piezoelectric material can have a problem where performance and reliability are lower than those of the PZT-based piezoelectric material. For example, the Pb-free piezoelectric material can have problem where the reliability of a piezoelectric material is affected by a low curie temperature and a piezoelectric characteristic is low due to a low piezoelectric constant. Accordingly, the inventors have invented a piezoelectric material having a characteristic which is the same as or similar to a Pb-based piezoelectric material, based on various research and experiments. This will be described below.

The first vibration portion 11 and the second vibration portion 12 according to an embodiment of the present disclosure can respectively include piezoelectric materials having different characteristics among Pb-free piezoelectric materials. For example, the first vibration portion 11 and the second vibration portion 12 can respectively include Pb-free piezoelectric materials having different characteristics. The different characteristics of the first vibration portion 11 and the second vibration portion 12 can include one or more of a curie temperature (T_{C}), a piezoelectric constant (d₃₃), a coercive field (E_{C}), a relative density (%), a theoretical density or specific gravity, and a dielectric constant (ε).

The curie temperature T_{C} can be a temperature where a crystalline structure of a piezoelectric material is changed to a cubic structure, can be a threshold temperature where a piezoelectric characteristic is reduced, and can be a factor which affects the reliability of a piezoelectric material. For example, one of the first vibration portion 11 and the second vibration portion 12 can include a piezoelectric material where the curie temperature T_{C} is 170° C. or more. For example, the piezoelectric material where the curie temperature T_{C} is 170° C. or more can implement or realize the enhancement of reliability of the piezoelectric device layer 10 or the piezoelectric device 1.

The piezoelectric constant d₃₃ can represent the amount of electric charges which are generated in a pressure direction applied to a piezoelectric material and can be a factor which affects a driving characteristic of a piezoelectric material. For example, one of the first vibration portion 11 and the second vibration portion 12 can include a piezoelectric material where the piezoelectric constant d₃₃ is 700 pC/N or more or is 650 pC/N to 800 pC/N. For example, the piezoelectric material where the piezoelectric constant d₃₃ is 700 pC/N or more or is 650 pC/N to 800 pC/N can implement or realize the enhancement of driving characteristic of the piezoelectric device layer 10 or the piezoelectric device 1.

The coercive field E_{C} can represent a magnitude of an electric field where polarization is 0 and can be a factor representing a large strain characteristic. For example, one of the first vibration portion 11 and the second vibration portion 12 can include a piezoelectric material where the coercive field E_{C} is 10 kV/cm or more. For example, the piezoelectric material where the coercive field E_{C} is 10 kV/cm or more can implement or realize a large strain characteristic of the piezoelectric device layer 10 or the piezoelectric device 1.

The relative density (%) can be a percentage where a measurement density based on sintering of a piezoelectric material is divided by a theoretical density and can be a factor representing a sintering characteristic. For example, one of the first vibration portion 11 and the second vibration portion 12 can include a piezoelectric material where the relative density (%) is 90% or more or is 95% or more.

The first vibration portion 11 and the second vibration portion 12 according to an embodiment of the present disclosure can include one or more of different characteristics.

One of the first vibration portion 11 and the second vibration portion 12 can include one or more of a relative density of 90% or more and a curie temperature of 170° C. or more. For example, one of the first vibration portion 11 and the second vibration portion 12 can include a piezoelectric material including a relative density of 90% or more and a curie temperature of 170° C. or more. Also, the piezoelectric material including a relative density of 90% or more and a curie temperature of 170° C. or more can include a piezoelectric constant of 650 pC/N to 800 pC/N. For example, one of the first vibration portion 11 and the second vibration portion 12 can include a piezoelectric material including a relative density of 90% or more, a curie temperature of 170° C. or more, and a piezoelectric constant of 650 pC/N to 800 pC/N. For example, one of the first vibration portion 11 and the second vibration portion 12 can include a piezoelectric material including one or more of a relative density of 90% or more, a curie temperature of 170° ° C. or more, and a piezoelectric constant of 650 pC/N to 800 pC/N, and the other of the first vibration portion 11 and the second vibration portion 12 can include a piezoelectric material having a different characteristic.

One of the first vibration portion 11 and the second vibration portion 12 can include one or more of a relative density of 95% or more and a piezoelectric constant of 700 pC/N or more. For example, one of the first vibration portion 11 and the second vibration portion 12 can include a piezoelectric material including a relative density of 95% or more and a piezoelectric constant of 700 pC/N or more. For example, one of the first vibration portion 11 and the second vibration portion 12 can include a piezoelectric material including one or more of a relative density of 95% or more and a piezoelectric constant of 700 pC/N or more, and the other of the first vibration portion 11 and the second vibration portion 12 can include a piezoelectric material having a different characteristic.

One of the first vibration portion 11 and the second vibration portion 12 can include one or more of a coercive field of 10 kV/cm or more and a piezoelectric constant of 200 pC/N to 500 pC/N. For example, one of the first vibration portion 11 and the second vibration portion 12 can include a piezoelectric material including a coercive field of 10 kV/cm or more and a piezoelectric constant of 200 pC/N to 500 pC/N. For example, one of the first vibration portion 11 and the second vibration portion 12 can include a piezoelectric material including one or more of a coercive field of 10 kV/cm or more and a piezoelectric constant of 200 pC/N to 500 pC/N, and the other of the first vibration portion 11 and the second vibration portion 12 can include a piezoelectric material having a different characteristic.

The first vibration portion 11 and the second vibration portion 12 can include different materials of a potassium sodium niobate (KNN)-based piezoelectric material including potassium (K), sodium (Na), and niobium (Nb), a barium titanate (BT)-based piezoelectric material, and a bismuth (Bi)-based piezoelectric material. For example, the KNN-based piezoelectric material can include (K,Na)NbO₃, but embodiments of the present disclosure are not limited thereto. For example, the BT-based piezoelectric material can include (Ba,Ca)TiO₃—Ba(Ti,Zr)O₃, but embodiments of the present disclosure are not limited thereto. For example, the Bi-based piezoelectric material can include at least one of (Na,Bi)TiO₃—BaTiO₃, BiFeO₃, Bi_{0.5}Na_{0.5}TiO₃(BNT), Bi(Na,K)TiO₃-BT-KNN, and (Bi,Na)TiO₃, but embodiments of the present disclosure are not limited thereto. Also, templated grain growth (TGG) can be applied to the KNN-based piezoelectric material, or may not be applied thereto. For example, one of the first vibration portion 11 and the second vibration portion 12 can include a KNN-based piezoelectric material to which TGG is applied, and the other of the first vibration portion 11 and the second vibration portion 12 can include a KNN-based piezoelectric material to which TGG is not applied.

Each of the first vibration portion 11 and the second vibration portion 12 of the piezoelectric device layer 10 according to an embodiment of the present disclosure can include one or more material layers. For example, the first vibration portion 11 can include one or more first material layers 11-1 to 11-3. The second vibration portion 12 can include one or more second material layers 12-1 and 12-2. The one or more first material layers 11-1 to 11-3 and the one or more second material layers 12-1 and 12-2 can have different characteristics. For example, the one or more first material layers 11-1 to 11-3 and the one or more second material layers 12-1 and 12-2 can include piezoelectric materials having different characteristics. For example, the one or more first material layers 11-1 to 11-3 and the one or more second material layers 12-1 and 12-2 can include Pb-free piezoelectric materials. For example, the one or more first material layers 11-1 to 11-3 and the one or more second material layers 12-1 and 12-2 can include Pb-free piezoelectric materials having different characteristics.

According to an embodiment of the present disclosure, each of the one or more first material layers 11-1 to 11-3 can include a piezoelectric material including one or more of a higher curie temperature and a less piezoelectric constant than those of each of the one or more second material layers 12-1 and 12-2.

Each of the one or more first material layers 11-1 to 11-3 can include one or more of a relative density of 90% or more and a curie temperature of 170° ° C. or more. For example, each of the one or more first material layers 11-1 to 11-3 can include a piezoelectric material including a relative density of 90% or more and a curie temperature of 170° C. or more. For example, each of the one or more first material layers 11-1 to 11-3 can include a KNN-based piezoelectric material including K, Na, and Nb. The one or more first material layers 11-1 to 11-3 can be configured or implemented to enhance or improve the reliability of the piezoelectric device layer 10 or the piezoelectric device 1.

For example, the one or more first material layers 11-1 to 11-3 can be represented by the following Chemical Formula 1.

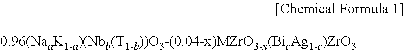

In Chemical Formula 1, T can denote antimony (Sb) or tantalum (Ta), M can denote strontium (Sr), barium (Ba), or calcium (Ca), 0.40≤a≤0.60, 0.90≤b≤0.98, 0.30≤c≤0.70, and 0.00≤x≤0.04.

In a case where TGG is applied, NaNbO₃ and Fe₂O₃ can be further included in Chemical Formula 1. For example, NaNbO₃ can be added to Chemical Formula 1 by 5 mol % or less and Fe₂O₃ can be added to Chemical Formula 1 by 5 mol % or less, but embodiments of the present disclosure are not limited thereto. In a case where TGG is not applied, Fe₂O₃ can be further included in Chemical Formula 1. For example, Fe₂O₃ can be added to Chemical Formula 1 by 5 mol % or less, but embodiments of the present disclosure are not limited thereto.

According to another embodiment, the one or more first material layers 11-1 to 11-3 can be represented by the following Chemical Formula 2.

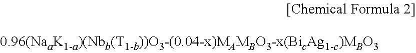

In Chemical Formula 2, T can denote antimony (Sb), tantalum (Ta), or vanadium (V), MA can denote Sr, Ba, or Ca, MB can denote zirconium (Zr), hafnium (Hf), titanium (Ti), or tin (Sn), E can denote the second material, 0.40≤a≤0.60, 0.90≤b≤1.00, 0.30≤c≤0.70, and 0.00≤x≤0.04.

In a case where TGG is applied, NaNbO₃ and Fe₂O₃ can be further included in Chemical Formula 2. For example, NaNbO₃ can be added to Chemical Formula 2 by 5 mol % or less and Fe₂O₃ can be added to Chemical Formula 2 by 5 mol % or less, but embodiments of the present disclosure are not limited thereto. In a case where TGG is not applied, Fe₂O₃ can be further included in Chemical Formula 2. For example, Fe₂O₃ can be added to Chemical Formula 2 by 5 mol % or less, but embodiments of the present disclosure are not limited thereto.

Each of the one or more second material layers 12-1 and 12-2 can have one or more of a relative density of 95% or more and a piezoelectric constant of 700 pC/N or more. For example, each of the one or more second material layers 12-1 and 12-2 can include a piezoelectric material which has a relative density of 95% or more and a piezoelectric constant of 700 pC/N or more. For example, each of the one or more second material layers 12-1 and 12-2 can include a BT-based piezoelectric material. The BT-based piezoelectric material can include (Ba,Ca)TiO₃—Ba(Ti,Zr)O₃, but embodiments of the present disclosure are not limited thereto. The one or more second material layers 12-1 and 12-2 can be configured or implemented to enhance or improve a driving characteristic of the piezoelectric device layer 10 or the piezoelectric device 1.

According to an embodiment of the present disclosure, the reliability of the one or more second material layers 12-1 and 12-2 can be complemented based on a high relative density and/or a high curie temperature of the one or more first material layers 11-1 to 11-3, and a low piezoelectric characteristic of the one or more first material layers 11-1 to 11-3 can be complemented by the one or more second material layers 12-1 and 12-2 having a high relative density and/or a high piezoelectric constant.

According to an embodiment of the present disclosure, the one or more second material layers 12-1 and 12-2 can be configured between the one or more first material layers 11-1 and 11-3. For example, the BT-based piezoelectric material can be provided between KNN-based piezoelectric materials. For example, the one or more first material layers 11-1 and 11-3 can be provided more outward from the piezoelectric device 1 than the one or more second material layers 12-1 and 12-2. The KNN-based piezoelectric material can be provided more outward from the piezoelectric device 1 than the BT-based piezoelectric material. Because the KNN-based piezoelectric material is provided more outward (or vertically outward) from the piezoelectric device 1 than the BT-based piezoelectric material, a degradation in the piezoelectric device 1 caused by a low curie temperature of the BT-based piezoelectric material can be prevented, and thus, the reliability of the piezoelectric device 1 can be enhanced, thereby enhancing a vibration characteristic of the piezoelectric device 1 based on a high piezoelectric constant of the BT-based piezoelectric material.

According to an embodiment of the present disclosure, the number of second material layers 12-1 and 12-2 can be equal to or different from the number of one or more first material layers 11-1 to 11-3. For example, the number of one or more first material layers 11-1 to 11-3 can be more than the number of second material layers 12-1 and 12-2. For example, the one or more first material layers 11-1 to 11-3 can include a 1-1 material layer 11-1, a 1-2 material layer 11-2, and a 1-3 material layer 11-3. The one or more second material layers 12-1 and 12-2 can include a 2-1 material layer 12-1 and a 2-2 material layer 12-2. Some of the one or more first material layers 11-1 to 11-3 can be disposed or provided between the one or more second material layers 12-1 and 12-2. For example, the 2-1 material layer 11-1 provided at a lowermost layer of the piezoelectric device layer 10 among the one or more first material layers 11-1 to 11-3 can be configured to contact or be connected with the first electrode layer 21. Also, the 1-3 material layer 11-3 provided at an uppermost layer of the piezoelectric device layer 10 among the one or more first material layers 11-1 to 11-3 can be configured to contact or be connected with the second electrode layer 22. The one or more second material layers 12-1 and 12-2 can be disposed between the 1-1 material layer 11-1 and the 1-3 material layer 11-3. Also, the other of the one or more first material layers 11 can be disposed between the 1-1 material layer 11-1 and the 1-3 material layer 11-3. For example, the 1-2 material layer 11-1 can be disposed between the 1-1 material layer 11-1 and the 1-3 material layer 11-3.

Each of the one or more first material layers 11-1 to 11-3 and the one or more second material layers 12-1 and 12-2 can be individually formed through a tape casting process. Each of the one or more first material layers 11-1 to 11-3 and the one or more second material layers 12-1 and 12-2 can be configured or implemented to be alternately stacked. For example, the 1-1 material layer 11-1 can be disposed at a first surface (or an upper surface) of the first electrode layer 21. The 2-1 material layer 12-1 can be disposed at a first surface (or an upper surface) of the 1-1 material layer 11-1. Also, the 1-1 material layer 11-1 can be disposed between the first electrode layer 21 and the 2-1 material layer 12-1. Also, the 1-2 material layer 11-2 can be disposed at a first surface (or an upper surface) of the 2-1 material layer 12-1. Also, the 2-1 material layer 12-1 can be disposed between the 1-1 material layer 11-1 and the 1-2 material layer 11-2. Also, the 2-2 material layer 12-2 can be disposed at a first surface (or an upper surface) of the 1-2 material layer 11-2. Also, the 1-2 material layer 11-2 can be disposed between the 2-1 material layer 12-1 and the 2-2 material layer 12-2. Also, the 1-3 material layer 11-3 can be disposed at a first surface (or an upper surface) of the 2-2 material layer 12-2. Also, the 1-2 material layer 12-2 can be disposed between the 1-2 material layer 11-2 and the 1-3 material layer 11-3. Also, the second electrode layer 22 can be disposed at a first surface (or an upper surface) of the 1-3 material layer 11-3. Also, the 1-3 material layer 11-3 can be disposed between the 2-2 material layer 12-2 and the second electrode layer 22.

Each of the one or more first material layers 11-1 to 11-3 can have a thickness which differs from that of at least one second material layers 12-1 and 12-2, or can have a thickness which is greater than or equal to that of the at least one second material layers 12-1 and 12-2. According to an embodiment of the present disclosure, each of the one or more first material layers 11-1 to 11-3 can be configured to have a first thickness T1, and each of the at least one second material layers 12-1 and 12-2 can be configured to have a second thickness T2. The first thickness T1 of each of the one or more first material layers 11-1 to 11-3 and the second thickness T2 of each of the at least one second material layers 12-1 and 12-2 can have the same height or different heights. For example, the first thickness T1 and the second thickness T2 can have substantially the same height within an error range of a manufacturing process. A thickness of each of the one or more first material layers 11-1 to 11-3 and the at least one second material layers 12-1 and 12-2 can be adjusted to 30 μm to 100 μm. A thickness of each of the one or more first material layers 11-1 to 11-3 and the at least one second material layers 12-1 and 12-2 can be adjusted to 30 μm or less so as to implement a high electric field characteristic of a piezoelectric material, but embodiments of the present disclosure are not limited thereto.

The first electrode layer 21 and the second electrode layer 22 can be configured to face each other with the piezoelectric device layer 10 therebetween.

The first electrode layer 21 can be disposed at a second surface (or a lower surface) of the piezoelectric device layer 10. The first electrode layer 21 can have a size which is less than or equal to that of the piezoelectric device layer 10. For example, the first electrode layer 21 can be disposed at a second surface (or a lower surface) of the 2-1 material layer 11-1 provided at a lowermost layer of the piezoelectric device layer 10.

The second electrode layer 22 can be disposed at the first surface (or the upper surface) of the piezoelectric device layer 10. The second electrode layer 22 can have a size which is less than or equal to that of the piezoelectric device layer 10. For example, the second electrode layer 22 can be disposed at a first surface (or an upper surface) of the 1-3 material layer 11-3 provided at an uppermost layer of the piezoelectric device layer 10. The first electrode layer 21 and the second electrode layer 22 can have the same size or different sizes. For example, the first electrode layer 21 and the second electrode layer 22 can have substantially the same size within an error range of a manufacturing process.

According to an embodiment of the present disclosure, in order to prevent an electrical connection (or short circuit) between the first electrode layer 21 and the second electrode layer 22, each of the first electrode layer 21 and the second electrode layer 22 can be formed at the other portion, except an edge portion, of the piezoelectric device layer 10. For example, the first electrode layer 21 can be formed at the other whole portion, except an edge portion, of the second surface (or the lower surface) of the piezoelectric device layer 10. For example, the second electrode layer 22 can be formed at the other whole portion, except an edge portion, of the first surface (or the upper surface) of the piezoelectric device layer 10.

According to an embodiment of the present disclosure, each of the first electrode layer 21 and the second electrode layer 22 can include a transparent conductive material, a semitransparent conductive material, or an opaque conductive material. For example, the transparent or semitransparent conductive material can include indium tin oxide (ITO) or indium zinc oxide (IZO), but embodiments of the present disclosure are not limited thereto. The opaque conductive material can include gold (Au), silver (Ag), platinum (Pt), palladium (Pd), molybdenum (Mo), magnesium (Mg), or glass frit-containing Ag, or an alloy thereof, but embodiments of the present disclosure are not limited thereto, as other metals such as nickel (Ni) can be used. For example, each of the first electrode layer 21 and the second electrode layer 22 can include Ag having low resistivity, so as to enhance an electrical characteristic and/or a vibration characteristic of the piezoelectric device layer 10. For example, carbon can be used for at least one of the first electrode layer 21 and the second electrode layer 22, and carbon can be a carbon material including graphite, carbon black, ketjen black, and carbon nanotube. In various embodiments of the present disclosure, the one or more middle electrode layers 23 can include the same or similar materials as those of the first electrode layer 21 or the second electrode layer 22, including the transparent conductive material, the semitransparent conductive material, or the opaque conductive material.

The piezoelectric device layer 10 according to an embodiment of the present disclosure can further include one or more middle electrode layers 23.

The one or more middle electrode layers 23 can be disposed or interposed between adjacent material layers among the one or more first material layers 11-1 to 11-3 and the one or more second material layers 12-1 and 12-2 in the piezoelectric device layer 10. The one or more middle electrode layers 23 can have a size which is less than or equal to that of the piezoelectric device layer 10. For example, the one or more middle electrode layers 23 can have a size which is less than or equal to that of each of the one or more first material layers 11-1 to 11-3 and the one or more second material layers 12-1 and 12-2. The one or more middle electrode layers 23 can have the same size or different sizes. For example, the one or more middle electrode layers 23 can have substantially the same size within an error range of a manufacturing process. According to an embodiment of the present disclosure, the one or more middle electrode layers 23 can include a material which is the same as or different from that of each of the first electrode layer 21 and the second electrode layer 22, but embodiments of the present disclosure are not limited thereto.

Each of the one or more first material layers 11-1 to 11-3 and the one or more second material layers 12-1 and 12-2 can be individually formed through a tape casting process. Each of the one or more first material layers 11-1 to 11-3 and the one or more second material layers 12-1 and 12-2 can be configured or implemented to be alternately stacked with the one or more middle electrode layers 23 therebetween. For example, the 1-1 material layer 11-1 can be disposed at the first surface (or the upper surface) of the first electrode layer 21. The 2-1 material layer 12-1 can be disposed at the first surface (or the upper surface) of the 1-1 material layer 11-1 with the middle electrode layer 23 therebetween. The 1-1 material layer 11-1 and the 2-1 material layer 12-1 can be electrically coupled to or electrically connected with each other through the middle electrode layer 23. Also, the 1-2 material layer 11-2 can be disposed at the first surface (or the upper surface) of the 2-1 material layer 12-1 with the middle electrode layers 23 therebetween. The 2-1 material layer 12-1 and the 1-2 material layer 11-2 can be electrically coupled to or electrically connected with each other through the middle electrode layer 23. Also, the 2-2 material layer 12-2 can be disposed at the first surface (or the upper surface) of the 1-2 material layer 11-2 with the middle electrode layer 23 therebetween. The 1-2 material layer 11-2 and the 2-2 material layer 12-2 can be electrically coupled to or electrically connected with each other through the middle electrode layer 23. Also, the 1-3 material layer 11-3 can be disposed at the first surface (or the upper surface) of the 2-2 material layer 12-2 with the middle electrode layers 23 therebetween. The 2-2 material layer 12-2 and the 1-3 material layer 11-3 can be electrically coupled to or electrically connected with each other through the middle electrode layer 23.

The piezoelectric device 1 according to the present disclosure can be configured so that a total thickness of the first electrode layer 21, the second electrode layer 22, the one or more middle electrode layers 23, and the piezoelectric device layer 10 is adjusted to tens μm to several mm. For example, the total thickness of the first electrode layer 21, the second electrode layer 22, the one or more middle electrode layers 23, and the piezoelectric device layer 10 can be adjusted to 100 μm to 200 μm, based on design-based details of the piezoelectric device 1, but embodiments of the present disclosure are not limited thereto.

In the piezoelectric device 1 according to an embodiment of the present disclosure, a process of manufacturing the piezoelectric device layer 10 according to an embodiment of the present disclosure will be described below.

First, each of the at least one first material layers 11-1 to 11-3 and the at least one second material layers 12-1 and 12-2 can be manufactured as a sheet having an appropriate thickness through an individual tape casting process. For example, a sheet of each of the at least one first material layers 11-1 to 11-3 can be formed by tape-casting a piezoelectric powder including a KNN-based piezoelectric material and a slurry including additives by using a tape casting apparatus (or a blade). Also, a sheet of each of the at least one second material layers 12-1 and 12-2 can be formed by tape-casting a piezoelectric powder including a BT-based piezoelectric material and a slurry including additives by using the tape casting apparatus (or the blade). For example, the one or more first material layers 11-1 to 11-3 can be represented by Chemical Formula 1 or Chemical Formula 2.

Sheets of the at least one first material layers 11-1 to 11-3 and sheets of the at least one second material layers 12-1 and 12-2, individually manufactured by a tape casting process, can be stacked in a predetermined sequence. The middle electrode layer 23 can be formed between adjacent sheets of the sheets of the at least one first material layers 11-1 to 11-3 and the sheets of the at least one second material layers 12-1 and 12-2. For example, a metal paste configuring the middle electrode layer 23 can be formed by coating (or forming) and drying (or curing) a sheet in a process of stacking the sheets of the at least one first material layers 11-1 to 11-3 and the sheets of the at least one second material layers 12-1 and 12-2.

The stacking of the sheets of the at least one first material layers 11-1 to 11-3, the sheets of the at least one second material layers 12-1 and 12-2, and the metal paste of the middle electrode layer 23 can be completed, and then, each material sheet can be stabilized by performing a warm isostatic press (WIP) process through primary molding. Also, a process of degreasing a primarily-molded stack material (or piezoelectric device layer) can be performed. A solvent or an organic material can be removed by a degreasing process. Then, a cold isostatic press (CIP) process can be performed through secondary molding. The CIP process can be used for increasing a density in a sintering process.

Subsequently, a sinter or the piezoelectric device layer 10 can be manufactured by sintering a green tape where the sheets of the at least one first material layers 11-1 to 11-3, the sheets of the at least one second material layers 12-1 and 12-2, and the metal paste of the middle electrode layer 23 are sequentially stacked.

According to an embodiment of the present disclosure, the sheets of the at least one first material layers 11-1 to 11-3 and the sheets of the at least one second material layers 12-1 and 12-2 having different characteristics can be provided in the sinter or the piezoelectric device layer 10, and thus, the sheets of the at least one first material layers 11-1 to 11-3 and the sheets of the at least one second material layers 12-1 and 12-2 can have different melting points, whereby it can be difficult to perform a sintering process under the same temperature condition.

Therefore, in a process of manufacturing the piezoelectric device layer 10 according to an embodiment of the present disclosure, a slurry of each of the at least one first material layers 11-1 to 11-3 can further include an additive (or a sintering agent). For example, the additive can include one or more of CuO, Fe₂O₃, La₂O₃, ZrO₂, ZnO, SnO₂, CdO, MnO₂, CuNb₂O₆, Gd₂O₃, Al₂O₃, CaO, BaO, HfO, TiO₂, Co₂O₃, NiO, MgO, B₂O₃, and SiO₂. The additive can adjust a sintering temperature of the at least one first material layers 11-1 to 11-3. For example, in a case where the additive is not added, the sintering temperature of the at least one first material layers 11-1 to 11-3 can have a temperature period of 1,250° C. to 1,400° C., and in a case where the additive is added, the sintering temperature of the at least one first material layers 11-1 to 11-3 can have a temperature period of 1,090° C. to 1,200° ° C.

Also, a slurry of each of the at least one second material layers 12-1 and 12-2 can further include a first additive and a second additive. For example, the first additive can include one or more of CuO, Fe₂O₃, La₂O₃, ZrO₂, ZnO, SnO₂, CdO, MnO₂, CuNb₂O₆, Gd₂O₃, Al₂O₃, CaO, BaO, HfO, TiO₂, Co₂O₃, NiO, MgO, B₂O₃, and SiO₂. For example, the second additive can include one or more of CaCl₂, AlF₃, BaCl₂, LiF, MgF₂, CaF₂, NaF, KF, NaCl, MgCl₂, KCl, ZnCl₂, LiCl₂, AlCl₃, CaSO₄, CaSO₃, Na₂SO₄, Na₂SO₃, and Na₂S. The first additive and the second additive can adjust a sintering temperature of the at least one second material layers 12-1 and 12-2. For example, in a case where the first additive and the second additive are not added, the sintering temperature of the at least one second material layers 12-1 and 12-2 can have a temperature period of 1,450° C. or more. Also, in a case where the first additive is added, the sintering temperature of the at least one second material layers 12-1 and 12-2 can have a temperature period of 1,250° C. to 1,400° C., and in a case where the second additive is added, the sintering temperature of the at least one second material layers 12-1 and 12-2 can have a temperature period of 1,090° C. to 1,200° C. Because the additives are added to the at least one first material layers 11-1 to 11-3 and the at least one second material layers 12-1 and 12-2, the sintering temperatures of the at least one first material layers 11-1 to 11-3 and the at least one second material layers 12-1 and 12-2 can be adjusted similarly, and a sintering process can be performed under the same condition.

According to an embodiment of the present disclosure, the sheets of the at least one first material layers 11-1 to 11-3 can be molded by using a slurry including no additive, and the sheets of the at least one second material layers 12-1 and 12-2 can be molded by using a slurry including the first additive including one or more of CuO, Fe₂O₃, La₂O₃, ZrO₂, ZnO, SnO₂, CdO, MnO₂, CuNb₂O₆, Gd₂O₃, Al₂O₃, CaO, BaO, HfO, TiO₂, Co₂O₃, NiO, MgO, B₂O₃, and SiO₂. For example, the first additive can be added by 0.1 wt % to 1.0 wt %, but embodiments of the present disclosure are not limited thereto. In this case, a green tape where the sheets of the at least one first material layers 11-1 to 11-3 and the sheets of the at least one second material layers 12-1 and 12-2 are stacked can be put into an electric furnace, sintered in a temperature range of 1,250° C. to 1,400° C., and naturally cooled at a room temperature, thereby manufacturing the piezoelectric device layer 10. For example, a sintering temperature can increase at a speed of 5° C./min and a sintering maintenance time can be 2 hours to 8 hours, but embodiments of the present disclosure are not limited thereto. According to an embodiment of the present disclosure, a sintering temperature of each of the at least one first material layers 11-1 to 11-3 and the at least one second material layers 12-1 and 12-2 can have a similar temperature range of 1,250° C. to 1,400° C., and thus, a sintering process can be simultaneously performed under the same temperature condition.

According to another embodiment of the present disclosure, the sheets of the at least one first material layers 11-1 to 11-3 can be molded by using a slurry to which the additive including one or more of CuO, Fe₂O₃, La₂O₃, ZrO₂, ZnO, SnO₂, CdO, MnO₂, CuNb₂O₆, Gd₂O₃, Al₂O₃, CaO, BaO, HfO, TiO₂, Co₂O₃, NiO, MgO, B₂O₃, and SiO₂ is added by 0.5 wt %, and the sheets of the at least one second material layers 12-1 and 12-2 can be molded by using a slurry to which the second additive including one or more of CaCl₂, AlF₃, BaCl₂, LiF, MgF₂, CaF₂, NaF, KF, NaCl, MgCl₂, KCl, ZnCl₂, LiCl₂, AlCl₃, CaSO₄, CaSO₃, Na₂SO₄, Na₂SO₃, and Na₂S is added by 0.1 wt % to 2.0 wt %, but embodiments of the present disclosure are not limited thereto. The second additive included in the at least one second material layers 12-1 and 12-2 can be adjusted to be similar to the sintering temperature of each of the at least one first material layers 11-1 to 11-3 by doping fluoride and/or chloride in addition to metal oxide, so as to increase a diffusion speed from a low temperature. A green tape where the sheets of the at least one first material layers 11-1 to 11-3 and the sheets of the at least one second material layers 12-1 and 12-2 are stacked can be put into an electric furnace, sintered in a temperature range of 1,090° ° C. to 1,200° ° C., and naturally cooled at a room temperature, thereby manufacturing the sinter or the piezoelectric device layer 10. For example, a sintering temperature can increase at a speed of 5° C./min and a sintering maintenance time can be 2 hours to 8 hours, but embodiments of the present disclosure are not limited thereto. According to another embodiment of the present disclosure, a sintering temperature of each of the at least one first material layers 11-1 to 11-3 and the at least one second material layers 12-1 and 12-2 can have a similar temperature range of 1,090° C. to 1,200° C., and thus, a sintering process can be simultaneously performed under the same temperature condition.

Subsequently, the first electrode layer 21 and the second electrode layer 22 can be formed in the sinter or the piezoelectric device layer 10, and the piezoelectric device 1 can be manufactured through a polarization (or polling) process.

In the piezoelectric device 1 according to an embodiment of the present disclosure, the piezoelectric device layer 10 need not include Pb, and the reliability and driving characteristic of the piezoelectric device layer 10 or the piezoelectric device 1 can be enhanced or improved. Also, because the piezoelectric device layer 10 does not include Pb, a production restriction material can be reduced and replacement of a harmful material can be implemented, and thus, an environment-friendly piezoelectric device 1 and an apparatus including the same can be implemented or realized.

In the embodiment of the present disclosure of FIG. 1, provides is the piezoelectric device layer 10 being laminated with the first electrode layer 21 and the second electrode layer 22. Also provided is the first vibration portion 11 and the second vibration portion 12 being laminated with the one or more middle electrode layer 23. For example, the one or more first material layers 11-1 to 11-3 and the one or more second material layers 12-1 and 12-2 in the piezoelectric device layer 10 can be laminated with the one or more middle electrode layer 23 in sequence, such as a multilayer structure. In various embodiments of the present disclosure, the piezoelectric device 1 can include micro-delaminated portions or micro-voids between the one or more first material layers 11-1 to 11-3 and the one or more second material layers 12-1 and 12-2 in the piezoelectric device layer 10 with the one or more middle electrode layer 23, or within the one or more first material layers 11-1 to 11-3 and the one or more second material layers 12-1 and 12-2 in the piezoelectric device layer 10. Such micro-delaminated portions or micro-voids can be equal to or smaller than the thickness T1 or T2. For example, a length of the micro-delamination can be equal to or smaller than the thickness T1 or T2, or both a height and a length of the micro-void can be equal to or smaller than the thickness T1 or T2, but the embodiments of the present disclosure are not limited thereto, and the dimensions of such micro-delaminated portions or micro-voids can vary without affecting the characteristics or performance of the piezoelectric device 1.

Further, in various embodiments of the present disclosure, the laminated structure of the one or more first material layers 11-1 to 11-3, the one or more second material layers 12-1 and 12-2, and the one or more middle electrode layer 23 can have substantially flat or smooth contact surfaces therebetween, but the embodiments of the present disclosures are not limited thereto, and the contact surfaces between adjacent first materials layer 11-1 to 11-3 and the middle electrode layers 23, or between adjacent second materials layer 12-1 and 12-2 and the middle electrode layers 23 can be rough or have variances. Such roughness or variances can include the above mentioned micro-delaminated portions or micro-voids, or can be other irregularities, such as protrusions and can have a size that can be equal to or less than a thickness of the one or more middle electrode layers 23, but embodiments of the present disclosures are not limited thereto.

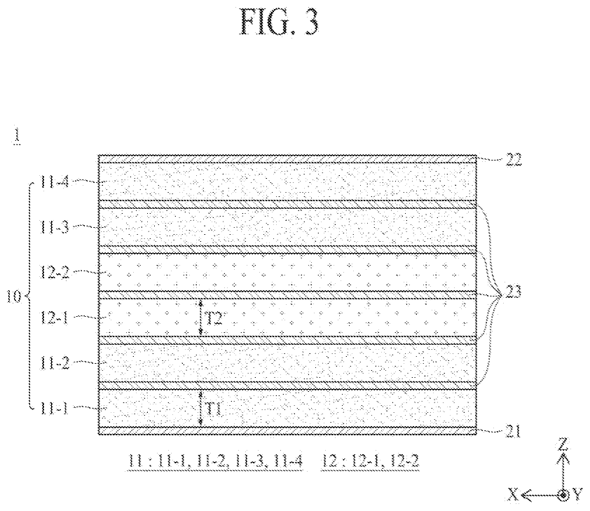

FIGS. 2 to 5 illustrate another structure of a piezoelectric device according to another embodiment of the present disclosure. Particularly, FIGS. 2 to 5 illustrate various embodiments of an arrangement structure of a piezoelectric device layer 10 in the piezoelectric devices 1 described above with reference to FIG. 1. In the following description, therefore, the same elements other than an arrangement structure of a piezoelectric device layer 10 and relevant elements are referred to by like reference numerals, and repeated descriptions thereof are omitted or will be briefly given.

Referring to FIG. 2, a piezoelectric device 1 according to an embodiment of the present disclosure can include a piezoelectric device layer 10, a first electrode layer 21, a second electrode layer 22, and one or more middle electrode layers 23.

Each of a first vibration portion 11 and a second vibration portion 12 of a piezoelectric device layer 10 according to another embodiment of the present disclosure can include one or more material layers. For example, the first vibration portion 11 can include one or more first material layers 11-1 and 11-2. The second vibration portion 12 can include one second material layer 12. The one or more first material layers 11-1 and 11-2 and the one second material layer 12 can have different characteristics. For example, the one or more first material layers 11-1 and 11-2 and the one second material layer 12 can include piezoelectric materials having different characteristics. For example, the one or more first material layers 11-1 and 11-2 and the one second material layer 12 can include Pb-free piezoelectric materials. For example, the one or more first material layers 11-1 and 11-2 and the one second material layer 12 can include Pb-free piezoelectric materials having different characteristics.

According to another embodiment of the present disclosure, each of the one or more first material layers 11-1 and 11-2 can include a piezoelectric material including one or more of a higher curie temperature and a less piezoelectric constant than those of the one second material layer 12.

Each of the one or more first material layers 11-1 and 11-2 can include one or more of a relative density of 90% or more and a curie temperature of 170° C. or more. For example, each of the one or more first material layers 11-1 and 11-2 can include a piezoelectric material including a relative density of 90% or more and a curie temperature of 170° C. or more. For example, each of the one or more first material layers 11-1 and 11-2 can include a KNN-based piezoelectric material including K, Na, and Nb. For example, the KNN-based piezoelectric material can include (K,Na)NbO₃, but embodiments of the present disclosure are not limited thereto. The one or more first material layers 11-1 and 11-2 can be configured or implemented to enhance or improve the reliability of the piezoelectric device layer 10 or the piezoelectric device 1. For example, the one or more first material layers 11-1 and 11-2 can be represented by Chemical Formula 1 or Chemical Formula 2.

The one second material layer 12 can have one or more of a relative density of 95% or more and a piezoelectric constant of 700 pC/N or more. For example, the one second material layer 12 can include a piezoelectric material which has a relative density of 95% or more and a piezoelectric constant of 700 pC/N or more. For example, the one second material layer 12 can include a BT-based piezoelectric material. For example, the BT-based piezoelectric material can include Ba(Ti,Zr)O₃ or (Ba,Ca)TiO₃—Ba(Ti,Zr)O₃, but embodiments of the present disclosure are not limited thereto. The one second material layer 12 can be configured or implemented to enhance or improve a driving characteristic of the piezoelectric device layer 10 or the piezoelectric device 1.

According to another embodiment of the present disclosure, the second material layer 12 can be configured between the one or more first material layers 11-1 and 11-2. For example, the BT-based piezoelectric material can be provided between KNN-based piezoelectric materials. For example, the one or more first material layers 11-1 and 11-2 can be provided more outward from the piezoelectric device 1 than the second material layer 12. The KNN-based piezoelectric material can be provided more outward from the piezoelectric device 1 than the BT-based piezoelectric material. Because the KNN-based piezoelectric material is provided more outward (or vertically outward) from the piezoelectric device 1 than the BT-based piezoelectric material, a degradation in the piezoelectric device 1 caused by a low curie temperature of the BT-based piezoelectric material can be prevented, and thus, the reliability of the piezoelectric device 1 can be enhanced, thereby enhancing a vibration characteristic of the piezoelectric device 1 based on a high piezoelectric constant of the BT-based piezoelectric material.

According to another embodiment of the present disclosure, the number of one or more first material layers 11-1 and 11-2 can be more than the number of one second material layer 12-1. For example, the one or more first material layers 11-1 and 11-2 can include a 1-1 material layer 11-1 and a 1-2 material layer 11-2. The one second material layer 12 can be configured with a single layer. For example, the 1-1 material layer 11-1 provided at a lowermost layer of the piezoelectric device layer 10 among the one or more first material layers 11-1 and 11-2 can be configured to contact or be connected with the first electrode layer 21. Also, the 1-2 material layer 11-2 provided at an uppermost layer of the piezoelectric device layer 10 among the one or more first material layers 11-1 and 11-2 can be configured to contact or be connected with the second electrode layer 22. The second material layer 12 can be disposed between the 1-1 material layer 11-1 and the 1-2 material layer 11-2.

Each of the one or more first material layers 11-1 and 11-2 and the one second material layer 12 can be individually formed through a tape casting process. Each of the one or more first material layers 11-1 and 11-2 and the one second material layer 12 can be configured or implemented to be alternately stacked. For example, the 1-1 material layer 11-1 can be disposed at a first surface (or an upper surface) of the first electrode layer 21. The second material layer 12 can be disposed at a first surface (or an upper surface) of the 1-1 material layer 11-1. Also, the 1-1 material layer 11-1 can be disposed between the first electrode layer 21 and the second material layer 12. Also, the 1-2 material layer 11-2 can be disposed at a first surface (or an upper surface) of the second material layer 12. Also, the second material layer 12 can be disposed between the 1-1 material layer 11-1 and the 1-2 material layer 11-2. Also, the second electrode layer 22 can be disposed at a first surface (or an upper surface) of the 1-2 material layer 11-2. Also, the 1-2 material layer 11-2 can be disposed between the second material layer 12 and the second electrode layer 22.

Each of the one or more first material layers 11-1 and 11-2 can have a thickness which differs from that of the one second material layer 12, or can have a thickness which is greater than or equal to that of the one second material layer 12. According to an embodiment of the present disclosure, each of the one or more first material layers 11-1 and 11-2 can be configured to have a third thickness T3, and the one second material layer 12 can be configured to have the second thickness T2. The third thickness T3 of each of the one or more first material layers 11-1 and 11-2 can have a height which is greater than the second thickness T2 of the one second material layer 12. For example, the one or more first material layers 11-1 and 11-2 can be configured to have a height which is greater than that of the one second material layer 12, so as to implement the high reliability and high heat resistance of the piezoelectric device layer 10 or the piezoelectric device 1. Also, the KNN-based piezoelectric material included in the one or more first material layers 11-1 and 11-2 can have a density of 4.0 g/cm³ to 4.7 g/cm³, and the BT-based piezoelectric material included in the one second material layer 12 can have a density of 5.7 g/cm³ to 6.0 g/cm³. Therefore, because the one or more first material layers 11-1 and 11-2 have a density which is relatively lower than that of the one second material layer 12, a blocking force which is greater than the one second material layer 12 can act thereon, and due to this, vibration intensity can be weakened. Accordingly, according to another embodiment of the present disclosure, in order to complement a reduction in vibration intensity of the one or more first material layers 11-1 and 11-2, a thickness of each of the one or more first material layers 11-1 and 11-2 can be adjusted to have a height which is two or more times a thickness of the one second material layer 12, but embodiments of the present disclosure are not limited thereto. For example, a blocking force can be external pressure where a displacement of a piezoelectric device is 0.

In the piezoelectric device 1 according to an embodiment of the present disclosure, except for that a configuration of each of the one or more first material layers 11-1 and 11-2 and the one second material layer 12 is modified, a process of manufacturing the piezoelectric device layer 10 according to another embodiment of the present disclosure can be the same as the descriptions of FIG. 1, and thus, repeated descriptions thereof are omitted.

The piezoelectric device 1 according to another embodiment of the present disclosure can have substantially the same effect as that of the piezoelectric device 1 described above with reference to FIG. 1. In the piezoelectric device 1 according to another embodiment of the present disclosure, the one or more first material layers 11-1 and 11-2 can increase more in weight than the one second material layer 12 and a thickness of each of the one or more first material layers 11-1 and 11-2 can be greater than that of the one second material layer 12, and thus, the reliability of the piezoelectric device layer 10 or the piezoelectric device 1 can be more enhanced or improved and a high heat resistance characteristic of the piezoelectric device layer 10 or the piezoelectric device 1 can be implemented or realized. For example, the piezoelectric device 1 according to another embodiment of the present disclosure can be implemented or equipped in an equipment apparatus of a vehicle or a vehicular or automotive apparatus, requiring high reliability and high heat resistance characteristic.

Referring to FIG. 3, a piezoelectric device 1 according to an embodiment of the present disclosure can include a piezoelectric device layer 10, a first electrode layer 21, a second electrode layer 22, and one or more middle electrode layers 23.

Each of a first vibration portion 11 and a second vibration portion 12 of a piezoelectric device layer 10 according to another embodiment of the present disclosure can include one or more material layers. For example, the first vibration portion 11 can include one or more first material layers 11-1 to 11-4. The second vibration portion 12 can include one or more second material layers 12-1 and 12-2. The one or more first material layers 11-1 to 11-4 and the one or more second material layers 12-1 and 12-2 can have different characteristics. For example, the one or more first material layers 11-1 and 11-2 and the one second material layer 12 can include piezoelectric materials having different characteristics. For example, the one or more first material layers 11-1 to 11-4 and the one or more second material layers 12-1 and 12-2 can include Pb-free piezoelectric materials. For example, the one or more first material layers 11-1 to 11-4 and the one or more second material layers 12-1 and 12-2 can include Pb-free piezoelectric materials having different characteristics.

According to another embodiment of the present disclosure, each of the one or more first material layers 11-1 to 11-4 can include a piezoelectric material including one or more of a higher curie temperature and a less piezoelectric constant than those of each of the one or more second material layers 12-1 and 12-2.

Each of the one or more first material layers 11-1 to 11-4 can include one or more of a relative density of 90% or more and a curie temperature of 170° C. or more. For example, each of the one or more first material layers 11-1 to 11-4 can include a piezoelectric material including a relative density of 90% or more and a curie temperature of 170° C. or more. For example, each of the one or more first material layers 11-1 to 11-4 can include a KNN-based piezoelectric material including K, Na, and Nb. For example, the KNN-based piezoelectric material can include (K,Na)NbO₃, but embodiments of the present disclosure are not limited thereto. The one or more first material layers 11-1 to 11-4 can be configured or implemented to enhance or improve the reliability of the piezoelectric device layer 10 or the piezoelectric device 1. For example, the one or more first material layers 11-1 to 11-4 can be represented by Chemical Formula 1 or Chemical Formula 2.

Each of the one or more second material layers 12-1 and 12-2 can have one or more of a relative density of 95% or more and a piezoelectric constant of 700 pC/N or more. For example, each of the one or more second material layers 12-1 and 12-2 can include a piezoelectric material which has a relative density of 95% or more and a piezoelectric constant of 700 pC/N or more. For example, each of the one or more second material layers 12-1 and 12-2 can include a BT-based piezoelectric material. For example, the BT-based piezoelectric material can include Ba(Ti,Zr)O₃ or (Ba,Ca)TiO₃—Ba(Ti,Zr)O₃, but embodiments of the present disclosure are not limited thereto. The one or more second material layers 12-1 and 12-2 can be configured or implemented to enhance or improve a driving characteristic of the piezoelectric device layer 10 or the piezoelectric device 1.

The number of one or more first material layers 11-1 to 11-4 according to another embodiment of the present disclosure can be more than the number of one or more second material layers 12-1 and 12-2. For example, the one or more first material layers 11-1 to 11-4 can include a 1-1 material layer 11-1, a 1-2 material layer 11-2, a 1-3 material layer 11-3, and a 1-4 material layer 11-4. The one or more second material layers 12-1 and 12-2 can include a 2-1 material layer 12-1 and a 2-2 material layer 12-2. For example, the 1-1 material layer 11-1 provided at a lowermost layer of the piezoelectric device layer 10 among the one or more first material layers 11-1 to 11-4 can be configured to contact or be connected with the first electrode layer 21. Also, the 1-4 material layer 11-4 provided at an uppermost layer of the piezoelectric device layer 10 among the one or more first material layers 11-1 to 11-4 can be configured to contact or be connected with the second electrode layer 22. The one or more second material layers 12-1 and 12-2 can be disposed between the 1-1 material layer 11-1 and the 1-4 material layer 11-4. Also, the other of the one or more first material layers 11 can be disposed between the 1-1 material layer 11-1 and the 1-4 material layer 11-4. For example, the 1-2 material layer 11-1 and the 1-3 material layer 11-3 can be disposed between the 1-1 material layer 11-1 and the 1-4 material layer 11-4.

Each of the one or more first material layers 11-1 to 11-4 and the one or more second material layers 12-1 and 12-2 can be individually formed through a tape casting process. Each of the one or more first material layers 11-1 to 11-4 and the one or more second material layers 12-1 and 12-2 can be configured or implemented to be alternately stacked. For example, the one or more second material layers 12-1 and 12-2 can be disposed at a center of the piezoelectric device layer 10, and the one or more first material layers 11-1 to 11-4 can be disposed with the one or more second material layers 12-1 and 12-2 therebetween. For example, the 1-1 material layer 11-1 can be disposed at a first surface (or an upper surface) of the first electrode layer 21. The 1-2 material layer 11-2 can be disposed at a first surface (or an upper surface) of the 1-1 material layer 11-1. Also, the 1-1 material layer 11-1 can be disposed between the first electrode layer 21 and the 1-2 material layer 11-2. Also, the 2-1 material layer 12-1 can be disposed at a first surface (or an upper surface) of the 1-2 material layer 11-2. Also, the 1-2 material layer 11-2 can be disposed between the 1-1 material layer 11-1 and the 2-1 material layer 12-1. Also, the 2-2 material layer 12-2 can be disposed at a first surface (or an upper surface) of the 2-1 material layer 12-1. Also, the 2-1 material layer 12-1 can be disposed between the 1-2 material layer 11-2 and the 2-2 material layer 12-2. Also, the 1-3 material layer 11-3 can be disposed at a first surface (or an upper surface) of the 2-2 material layer 12-2. Also, the 2-2 material layer 12-2 can be disposed between the 2-1 material layer 12-1 and the 1-3 material layer 11-3. Also, the 1-4 material layer 11-4 can be disposed at a first surface (or an upper surface) of the 1-3 material layer 11-3. Also, the 1-3 material layer 11-3 can be disposed between the 2-2 material layer 12-2 and the 1-4 material layer 11-4. Also, the second electrode layer 22 can be disposed at a first surface (or an upper surface) of the 1-4 material layer 11-4. Also, the 1-4 material layer 11-4 can be disposed between the 1-3 material layer 11-3 and the second electrode layer 22.

Each of the one or more first material layers 11-1 to 11-4 can have a thickness which differs from that of the one or more second material layers 12-1 and 12-2, or can have a thickness which is greater than or equal to that of the one or more second material layers 12-1 and 12-2. According to an embodiment of the present disclosure, each of the one or more first material layers 11-1 to 11-4 can be configured to have the first thickness T1, and each of the one or more second material layers 12-1 and 12-2 can be configured to have the second thickness T2. The first thickness T1 of each of the one or more first material layers 11-1 to 11-4 and the second thickness T2 of each of the one or more second material layers 12-1 and 12-2 can have the same height or different heights. For example, the first thickness T1 and the second thickness T2 can have substantially the same height within an error range of a manufacturing process.

According to another embodiment of the present disclosure, the one or more first material layers 11-1 to 11-4 and the one or more second material layers 12-1 and 12-2 can be configured to have the same thicknesses T1 and T2. For example, the one or more second material layers 12-1 and 12-2 can be relatively lower in reliability than the one or more first material layers 11-1 to 11-4, and thus, the one or more second material layers 12-1 and 12-2 can be disposed adjacent to each other at a center of the piezoelectric device layer 10, the 1-1 material layer 11-1 and the 1-2 material layer 11-2 can be disposed adjacent to each other under the one or more second material layers 12-1 and 12-2, and the 1-3 material layer 11-3 and the 1-4 material layer 11-4 can be disposed adjacent to each other on the one or more second material layers 12-1 and 12-2. Accordingly, according to another embodiment of the present disclosure, the one or more second material layers 12-1 and 12-2 can be protected by the one or more first material layers 11-1 to 11-4 having relatively good reliability, thereby minimizing or preventing a reduction in reliability of the piezoelectric device layer 10 or the piezoelectric device 1.

According to another embodiment of the present disclosure, the one or more second material layers 12-1 and 12-2 can be configured between the one or more first material layers 11-1 to 11-4. For example, a BT-based piezoelectric material can be provided between KNN-based piezoelectric materials. For example, the one or more first material layers 11-1 to 11-4 can be provided at an outer portion of the piezoelectric device 1 with the one or more second material layers 12-1 and 12-2 therebetween. The KNN-based piezoelectric material can be provided at the outer portion of the piezoelectric device 1 with the BT-based piezoelectric material therebetween. Because the KNN-based piezoelectric material is provided at the outer portion (or upper and lower outer portion) of the piezoelectric device 1 with the BT-based piezoelectric material therebetween, a degradation in the piezoelectric device 1 caused by a low curie temperature of the BT-based piezoelectric material can be prevented, and thus, the reliability of the piezoelectric device 1 can be enhanced, thereby enhancing a vibration characteristic of the piezoelectric device 1 based on a high piezoelectric constant of the BT-based piezoelectric material.

In the piezoelectric device 1 according to an embodiment of the present disclosure, except for that a configuration of each of the one or more first material layers 11-1 to 11-4 and the one or more second material layers 12-1 and 12-2 is modified, a process of manufacturing the piezoelectric device layer 10 according to another embodiment of the present disclosure can be the same as the descriptions of FIG. 1, and thus, repeated descriptions thereof are omitted.

The piezoelectric device 1 according to another embodiment of the present disclosure can have substantially the same effect as that of the piezoelectric device 1 described above with reference to FIG. 1 or 2. In the piezoelectric device 1 according to another embodiment of the present disclosure, the one or more second material layers 12-1 and 12-2 can be disposed at a center of the piezoelectric device layer 10, and thus, a reduction in reliability of the piezoelectric device layer 10 or the piezoelectric device 1 can be minimized or prevented. For example, the piezoelectric device 1 according to another embodiment of the present disclosure can be implemented or equipped in an apparatus requiring high reliability and a high heat resistance characteristic.

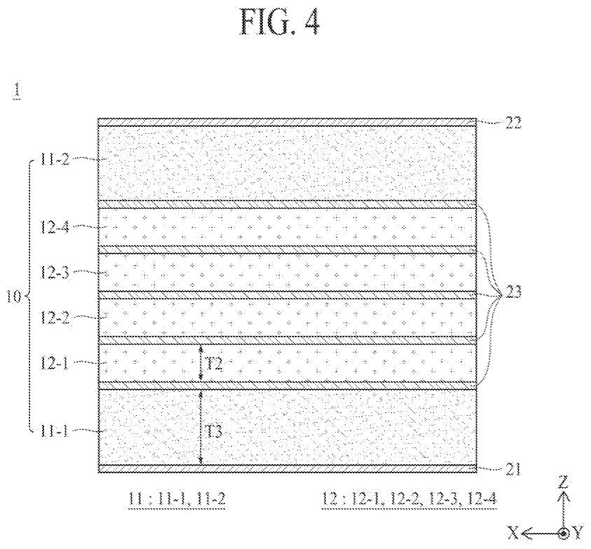

Referring to FIG. 4, a piezoelectric device 1 according to another embodiment of the present disclosure can include a piezoelectric device layer 10, a first electrode layer 21, a second electrode layer 22, and one or more middle electrodes 23.

Each of a first vibration portion 11 and a second vibration portion 12 of a piezoelectric device layer 10 according to another embodiment of the present disclosure can include one or more material layers. For example, the first vibration portion 11 can include one or more first material layers 11-1 and 11-2. The second vibration portion 12 can include one or more second material layers 12-1 to 12-4. The one or more first material layers 11-1 and 11-2 and the one or more second material layers 12-1 to 12-4 can have different characteristics. For example, the one or more first material layers 11-1 and 11-2 and the one or more second material layers 12-1 to 12-4 can include piezoelectric materials having different characteristics. For example, the one or more first material layers 11-1 and 11-2 and the one or more second material layers 12-1 to 12-4 can include Pb-free piezoelectric materials. For example, the one or more first material layers 11-1 and 11-2 and the one or more second material layers 12-1 to 12-4 can include Pb-free piezoelectric materials having different characteristics.

According to another embodiment of the present disclosure, each of the one or more first material layers 11-1 and 11-2 can include a piezoelectric material including one or more of a higher curie temperature and a less piezoelectric constant than those of each of the one or more second material layers 12-1 to 12-4.

Each of the one or more first material layers 11-1 and 11-2 can include one or more of a relative density of 90% or more and a curie temperature of 170° C. or more. For example, each of the one or more first material layers 11-1 and 11-2 can include a piezoelectric material including a relative density of 90% or more and a curie temperature of 170° C. or more. For example, each of the one or more first material layers 11-1 and 11-2 can include a KNN-based piezoelectric material including K, Na, and Nb. For example, the KNN-based piezoelectric material can include (K,Na)NbO₃, but embodiments of the present disclosure are not limited thereto. The one or more first material layers 11-1 and 11-2 can be configured or implemented to enhance or improve the reliability of the piezoelectric device layer 10 or the piezoelectric device 1. For example, the one or more first material layers 11-1 and 11-2 can be represented by Chemical Formula 1 or Chemical Formula 2.

Each of the one or more second material layers 12-1 to 12-4 can have one or more of a relative density of 95% or more and a piezoelectric constant of 700 pC/N or more. For example, each of the one or more second material layers 12-1 to 12-4 can include a piezoelectric material which has a relative density of 95% or more and a piezoelectric constant of 700 pC/N or more. For example, each of the one or more second material layers 12-1 to 12-4 can include a BT-based piezoelectric material. For example, the BT-based piezoelectric material can include Ba(Ti,Zr)O₃ or (Ba,Ca)TiO₃—Ba(Ti,Zr)O₃, but embodiments of the present disclosure are not limited thereto. The one or more second material layers 12-1 to 12-4 can be configured or implemented to enhance or improve a driving characteristic of the piezoelectric device layer 10 or the piezoelectric device 1.

The number of one or more first material layers 11-1 and 11-2 according to another embodiment of the present disclosure can be less than the number of one or more second material layers 12-1 to 12-4. For example, the one or more first material layers 11-1 and 11-2 can include a 1-1 material layer 11-1 and a 1-2 material layer 11-2. The one or more second material layers 12-1 to 12-4 can include a 2-1 material layer 12-1, a 2-2 material layer 12-2, a 2-3 material layer 12-3, and a 2-4 material layer 12-4. For example, the 1-1 material layer 11-1 provided at a lowermost layer of the piezoelectric device layer 10 among the one or more first material layers 11-1 and 11-2 can be configured to contact or be connected with the first electrode layer 21. Also, the 1-2 material layer 11-2 provided at an uppermost layer of the piezoelectric device layer 10 among the one or more first material layers 11-1 and 11-2 can be configured to contact or be connected with the second electrode layer 22. The one or more second material layers 12-1 to 12-4 can be disposed between the 1-1 material layer 11-1 and the 1-2 material layer 11-2.

Each of the one or more first material layers 11-1 and 11-2 and the one or more second material layers 12-1 to 12-4 can be individually formed through a tape casting process. Each of the one or more first material layers 11-1 and 11-2 and the one or more second material layers 12-1 to 12-4 can be configured or implemented to be alternately stacked. For example, the one or more second material layers 12-1 to 12-4 can be disposed at a center of the piezoelectric device layer 10, and the one or more first material layers 11-1 and 11-2 can be disposed with the one or more second material layers 12-1 to 12-4 therebetween. For example, the 1-1 material layer 11-1 can be disposed at a first surface (or an upper surface) of the first electrode layer 21. The 2-1 material layer 12-1 can be disposed at a first surface (or an upper surface) of the 1-1 material layer 11-1. Also, the 1-1 material layer 11-1 can be disposed between the first electrode layer 21 and the 2-1 material layer 12-1. Also, the 2-2 material layer 12-2 can be disposed at a first surface (or an upper surface) of the 2-1 material layer 12-1. Also, the 2-1 material layer 12-1 can be disposed between the 1-1 material layer 11-1 and the 2-2 material layer 12-2. Also, the 2-3 material layer 12-3 can be disposed at a first surface (or an upper surface) of the 2-2 material layer 12-2. Also, the 2-2 material layer 12-2 can be disposed between the 2-1 material layer 12-1 and the 2-3 material layer 12-3. Also, the 2-4 material layer 12-4 can be disposed at a first surface (or an upper surface) of the 2-3 material layer 12-3. Also, the 2-3 material layer 12-3 can be disposed between the 2-2 material layer 12-2 and the 2-4 material layer 12-4. Also, the 1-2 material layer 11-2 can be disposed at a first surface (or an upper surface) of the 2-4 material layer 12-4. Also, the 2-4 material layer 12-4 can be disposed between the 2-3 material layer 12-3 and the 1-2 material layer 11-2. Also, the second electrode layer 22 can be disposed at a first surface (or an upper surface) of the 1-2 material layer 11-2. Also, the 1-2 material layer 11-2 can be disposed between the 2-4 material layer 12-4 and the second electrode layer 22.

Each of the one or more first material layers 11-1 and 11-2 can have a thickness which differs from that of the one or more second material layers 12-1 to 12-4, or can have a thickness which is greater than or equal to that of the one or more second material layers 12-1 to 12-4. According to an embodiment of the present disclosure, each of the one or more first material layers 11-1 and 11-2 can be configured to have the third thickness T3, and the one or more second material layers 12-1 to 12-4 can be configured to have the second thickness T2. The third thickness T3 of each of the one or more first material layers 11-1 and 11-2 can have a height which is greater than the second thickness T2 of the one or more second material layers 12-1 to 12-4. Also, the KNN-based piezoelectric material included in the one or more first material layers 11-1 and 11-2 can have a density of 4.0 g/cm³ to 4.7 g/cm³, and the BT-based piezoelectric material included in the one or more second material layers 12-1 to 12-4 can have a density of 5.7 g/cm³ to 6.0 g/cm³. Therefore, because the one or more first material layers 11-1 and 11-2 have a density which is relatively lower than that of each of the one or more second material layers 12-1 to 12-4, a blocking force which is greater than the one or more second material layers 12-1 to 12-4 can act thereon, and due to this, vibration intensity can be weakened. Accordingly, according to another embodiment of the present disclosure, in order to complement a reduction in vibration intensity of the one or more first material layers 11-1 and 11-2, a thickness of each of the one or more first material layers 11-1 and 11-2 can be adjusted to have a height which is 1.5 to 3 times a thickness of each of the one or more second material layers 12-1 to 12-4, but embodiments of the present disclosure are not limited thereto.

According to another embodiment of the present disclosure, the one or more second material layers 12-1 to 12-4 can be configured between the one or more first material layers 11-1 and 11-2. For example, a BT-based piezoelectric material can be provided between KNN-based piezoelectric materials. For example, the one or more first material layers 11-1 and 11-2 can be provided at an outer portion of the piezoelectric device 1 with the one or more second material layers 12-1 to 12-4 therebetween. The KNN-based piezoelectric material can be provided at the outer portion of the piezoelectric device 1 with the BT-based piezoelectric material therebetween. Because the KNN-based piezoelectric material is provided at the outer portion (or upper and lower outer portion) of the piezoelectric device 1 with the BT-based piezoelectric material therebetween, a degradation in the piezoelectric device 1 caused by a low curie temperature of the BT-based piezoelectric material can be prevented, and thus, the reliability of the piezoelectric device 1 can be enhanced, thereby enhancing a vibration characteristic of the piezoelectric device 1 based on a high piezoelectric constant of the BT-based piezoelectric material.

In the piezoelectric device 1 according to an embodiment of the present disclosure, except for that a configuration of each of the one or more first material layers 11-1 and 11-2 and the one or more second material layers 12-1 to 12-4 is modified, a process of manufacturing the piezoelectric device layer 10 according to another embodiment of the present disclosure can be the same as the descriptions of FIG. 1, and thus, repeated descriptions thereof are omitted.

The piezoelectric device 1 according to another embodiment of the present disclosure can have substantially the same effect as that of the piezoelectric device 1 described above with reference to FIGS. 1 to 3. In the piezoelectric device 1 according to another embodiment of the present disclosure, the number of one or more second material layers 12-1 to 12-4 can increase more than the number of one or more first material layers 11-1 and 11-2 and a thickness of each of the one or more first material layers 11-1 and 11-2 can be greater than that of each of the one or more second material layers 12-1 to 12-4, and thus, a driving characteristic of the piezoelectric device layer 10 or the piezoelectric device 1 can be more enhanced or improved. For example, the piezoelectric device 1 according to another embodiment of the present disclosure can be implemented or equipped in an apparatus which is not large in influence of environment reliability and needs a high driving characteristic.

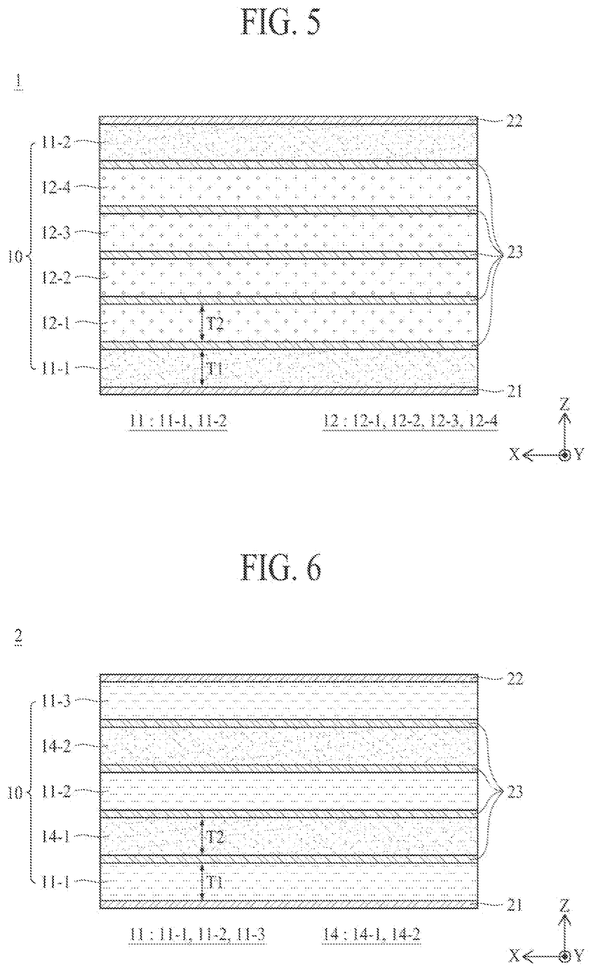

Referring to FIG. 5, a piezoelectric device 1 according to an embodiment of the present disclosure can include a piezoelectric device layer 10, a first electrode layer 21, a second electrode layer 22, and one or more middle electrode layers 23.

Each of a first vibration portion 11 and a second vibration portion 12 of a piezoelectric device layer 10 according to another embodiment of the present disclosure can include one or more material layers. For example, the first vibration portion 11 can include one or more first material layers 11-1 and 11-2. The second vibration portion 12 can include one or more second material layers 12-1 to 12-4. The one or more first material layers 11-1 and 11-2 and the one or more second material layers 12-1 to 12-4 can have different characteristics. For example, the one or more first material layers 11-1 and 11-2 and the one or more second material layers 12-1 to 12-4 can include piezoelectric materials having different characteristics. For example, the one or more first material layers 11-1 and 11-2 and the one or more second material layers 12-1 to 12-4 can include Pb-free piezoelectric materials. For example, the one or more first material layers 11-1 and 11-2 and the one or more second material layers 12-1 to 12-4 can include Pb-free piezoelectric materials having different characteristics.

According to another embodiment of the present disclosure, each of the one or more first material layers 11-1 and 11-2 can include a piezoelectric material including one or more of a higher curie temperature and a less piezoelectric constant than those of each of the one or more second material layers 12-1 to 12-4.

Each of the one or more first material layers 11-1 and 11-2 can include one or more of a relative density of 90% or more and a curie temperature of 170° C. or more. For example, each of the one or more first material layers 11-1 and 11-2 can include a piezoelectric material including a relative density of 90% or more and a curie temperature of 170° C. or more. For example, each of the one or more first material layers 11-1 and 11-2 can include a KNN-based piezoelectric material including K, Na, and Nb. For example, the KNN-based piezoelectric material can include (K,Na)NbO₃, but embodiments of the present disclosure are not limited thereto. The one or more first material layers 11-1 and 11-2 can be configured or implemented to enhance or improve the reliability of the piezoelectric device layer 10 or the piezoelectric device 1. For example, the one or more first material layers 11-1 and 11-2 can be represented by Chemical Formula 1 or Chemical Formula 2.

Each of the one or more second material layers 12-1 to 12-4 can have one or more of a relative density of 95% or more and a piezoelectric constant of 700 pC/N or more. For example, each of the one or more second material layers 12-1 to 12-4 can include a piezoelectric material which has a relative density of 95% or more and a piezoelectric constant of 700 pC/N or more. For example, each of the one or more second material layers 12-1 to 12-4 can include a BT-piezoelectric material. For example, the BT-based piezoelectric material can include Ba(Ti,Zr)O₃ or (Ba,Ca)TiO₃—Ba(Ti,Zr)O₃, but embodiments of the present disclosure are not limited thereto. The one or more second material layers 12-1 to 12-4 can be configured or implemented to enhance or improve a driving characteristic of the piezoelectric device layer 10 or the piezoelectric device 1.

The number of one or more first material layers 11-1 and 11-2 according to another embodiment of the present disclosure can be less than the number of one or more second material layers 12-1 to 12-4. For example, the one or more first material layers 11-1 and 11-2 can include a 1-1 material layer 11-1 and a 1-2 material layer 11-2. The one or more second material layers 12-1 to 12-4 can include a 2-1 material layer 12-1, a −2 material layer 12-2, a 2-3 material layer 12-3, and a 2-4 material layer 12-4. For example, the 1-1 material layer 11-1 provided at a lowermost layer of the piezoelectric device layer 10 among the one or more first material layers 11-1 and 11-2 can be configured to contact or be connected with the first electrode layer 21. Also, the 1-2 material layer 11-2 provided at an uppermost layer of the piezoelectric device layer 10 among the one or more first material layers 11-1 and 11-2 can be configured to contact or be connected with the second electrode layer 22. The one or more second material layers 12-1 to 12-4 can be disposed between the 1-1 material layer 11-1 and the 1-2 material layer 11-2.

Each of the one or more first material layers 11-1 and 11-2 and the one or more second material layers 12-1 to 12-4 can be individually formed through a tape casting process. Each of the one or more first material layers 11-1 and 11-2 and the one or more second material layers 12-1 to 12-4 can be configured or implemented to be alternately stacked. For example, the one or more second material layers 12-1 to 12-4 can be disposed at a center of the piezoelectric device layer 10, and the one or more first material layers 11-1 and 11-2 can be disposed with the one or more second material layers 12-1 to 12-4 therebetween. For example, the 1-1 material layer 11-1 can be disposed at a first surface (or an upper surface) of the first electrode layer 21. The 2-1 material layer 12-1 can be disposed at a first surface (or an upper surface) of the 1-1 material layer 11-1. Also, the 1-1 material layer 11-1 can be disposed between the first electrode layer 21 and the 2-1 material layer 12-1. Also, the 2-2 material layer 12-2 can be disposed at a first surface (or an upper surface) of the 2-1 material layer 12-1. Also, the 2-1 material layer 12-1 can be disposed between the 1-1 material layer 11-1 and the 2-2 material layer 12-2. Also, the 2-3 material layer 12-3 can be disposed at a first surface (or an upper surface) of the 2-2 material layer 12-2. Also, the 2-2 material layer 12-2 can be disposed between the 2-1 material layer 12-1 and the 2-3 material layer 12-3. Also, the 2-4 material layer 12-4 can be disposed at a first surface (or an upper surface) of the 2-3 material layer 12-3. Also, the 2-3 material layer 12-3 can be disposed between the 2-2 material layer 12-2 and the 2-4 material layer 12-4. Also, the 1-2 material layer 11-2 can be disposed at a first surface (or an upper surface) of the 2-4 material layer 12-4. Also, the 2-4 material layer 12-4 can be disposed between the 2-3 material layer 12-3 and the 1-2 material layer 11-2. Also, the second electrode layer 22 can be disposed at a first surface (or an upper surface) of the 1-2 material layer 11-2. Also, the 1-2 material layer 11-2 can be disposed between the 2-4 material layer 12-4 and the second electrode layer 22.

According to another embodiment of the present disclosure, the one or more second material layers 12-1 to 12-4 can be configured between the one or more first material layers 11-1 and 11-2. For example, a BT-based piezoelectric material can be provided between KNN-based piezoelectric materials. For example, the one or more first material layers 11-1 and 11-2 can be provided at an outer portion of the piezoelectric device 1 with the one or more second material layers 12-1 to 12-4 therebetween. The KNN-based piezoelectric material can be provided at the outer portion of the piezoelectric device 1 with the BT-based piezoelectric material therebetween. Because the KNN-based piezoelectric material is provided at the outer portion (or upper and lower outer portion) of the piezoelectric device 1 with the BT-based piezoelectric material therebetween, a degradation in the piezoelectric device 1 caused by a low curie temperature of the BT-based piezoelectric material can be prevented, and thus, the reliability of the piezoelectric device 1 can be enhanced, thereby enhancing a vibration characteristic of the piezoelectric device 1 based on a high piezoelectric constant of the BT-based piezoelectric material.

Each of the one or more first material layers 11-1 and 11-2 can have a thickness which differs from that of the one or more second material layers 12-1 to 12-4, or can have a thickness which is greater than or equal to that of the one or more second material layers 12-1 to 12-4. According to an embodiment of the present disclosure, each of the one or more first material layers 11-1 and 11-2 can be configured to have the first thickness T1, and each of the one or more second material layers 12-1 to 12-4 can be configured to have the second thickness T2. The first thickness T1 of each of the one or more first material layers 11-1 and 11-2 and the second thickness T2 of each of the one or more second material layers 12-1 to 12-4 can have the same height or different heights. For example, the first thickness T1 and the second thickness T2 can have substantially the same height within an error range of a manufacturing process.

In the piezoelectric device 1 according to an embodiment of the present disclosure, except for that a configuration of each of the one or more first material layers 11-1 and 11-2 and the one or more second material layers 12-1 to 12-4 is modified, a process of manufacturing the piezoelectric device layer 10 according to another embodiment of the present disclosure can be the same as the descriptions of FIG. 1, and thus, repeated descriptions thereof are omitted.

The piezoelectric device 1 according to another embodiment of the present disclosure can have substantially the same effect as that of the piezoelectric device 1 described above with reference to FIGS. 1 to 4. In the piezoelectric device 1 according to another embodiment of the present disclosure, the number of one or more second material layers 12-1 to 12-4 can increase more than the number of one or more first material layers 11-1 and 11-2 and a thickness of each of the one or more first material layers 11-1 and 11-2 can be equal to that of each of the one or more second material layers 12-1 to 12-4, and thus, a driving characteristic of the piezoelectric device layer 10 or the piezoelectric device 1 can be more enhanced or improved. According to another embodiment of the present disclosure, the piezoelectric device layer 10 or the piezoelectric device 1 satisfying various requirement conditions corresponding to a piezoelectric driving characteristic can be more easily manufactured.

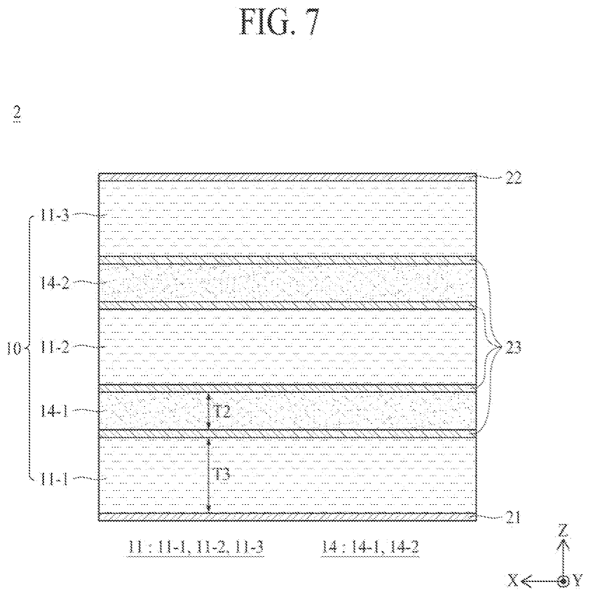

FIG. 6 illustrates a piezoelectric device according to another embodiment of the present disclosure. FIG. 7 illustrates another structure of a piezoelectric device according to another embodiment of the present disclosure. Particularly, FIGS. 6 and 7 illustrate an embodiment implemented by modifying a configuration of a piezoelectric device layer 10 in the piezoelectric devices 1 described above with reference to FIGS. 1 to 5. In the following description, therefore, the same elements other than a configuration of a piezoelectric device layer 10 and relevant elements are referred to by like reference numerals, and repeated descriptions thereof are omitted or will be briefly given.

Referring to FIGS. 6 and 7, the piezoelectric device 2 according to another embodiment of the present disclosure can include a piezoelectric device layer 10, a first electrode layer 21, a second electrode layer 22, and one or more middle electrode layers 23.

A first vibration portion 11 and a second vibration portion 14 according to another embodiment of the present disclosure can include one or more of different characteristics.

One of the first vibration portion 11 and the second vibration portion 14 can include one or more of a relative density of 90% or more and a curie temperature of 170° C. or more. For example, one of the first vibration portion 11 and the second vibration portion 14 can include a piezoelectric material including a relative density of 90% or more and a curie temperature of 170° C. or more. Also, the piezoelectric material including a relative density of 90% or more and a curie temperature of 170° C. or more can include a piezoelectric constant of 650 pC/N to 800 pC/N. For example, one of the first vibration portion 11 and the second vibration portion 14 can include a piezoelectric material including a relative density of 90% or more, a curie temperature of 170° C. or more, and a piezoelectric constant of 650 pC/N to 800 pC/N, and the other of the first vibration portion 11 and the second vibration portion 14 can include a piezoelectric material including a relative density of 95% or more and a curie temperature of 170° C. or more.

The first vibration portion 11 and the second vibration portion 14 can include a KNN-based piezoelectric material including K, Na, and Nb. For example, the KNN-based piezoelectric material can include (K,Na)NbO₃, but embodiments of the present disclosure are not limited thereto. For example, one of the first vibration portion 11 and the second vibration portion 14 can include a KNN-based piezoelectric material to which TGG is applied, and the other of the first vibration portion 11 and the second vibration portion 14 can include a KNN-based piezoelectric material to which TGG is not applied. For example, the first vibration portion 11 and the second vibration portion 14 can be represented by Chemical Formula 1 or Chemical Formula 2.

Each of the first vibration portion 11 and the second vibration portion 14 of the piezoelectric device layer 10 according to another embodiment of the present disclosure can include one or more material layers. For example, the first vibration portion 11 can include one or more first material layers 11-1 to 11-3. The second vibration portion 14 can include one or more second material layers 14-1 and 14-2. The one or more first material layers 11-1 to 11-3 and the one or more second material layers 14-1 and 14-2 can have different characteristics. For example, the one or more first material layers 11-1 to 11-3 and the one or more second material layers 14-1 and 14-2 can include piezoelectric materials having different characteristics. For example, the one or more first material layers 11-1 to 11-3 and the one or more second material layers 14-1 and 14-2 can include Pb-free piezoelectric materials. For example, the one or more first material layers 11-1 to 11-3 and the one or more second material layers 14-1 and 14-2 can include Pb-free piezoelectric materials having different characteristics.

According to an embodiment of the present disclosure, each of the one or more first material layers 11-1 to 11-3 can include a piezoelectric material including one or more of a higher piezoelectric constant, a lower curie temperature, and a lower relative density than those of each of the one or more second material layers 14-1 and 14-2. For example, each of the one or more first material layers 11-1 to 11-3 can include a KNN-based piezoelectric material to which TGG is applied. For example, each of the one or more first material layers 11-1 to 11-3 can be configured to have a relatively lower relative density and dielectric constant and a higher piezoelectric constant than those of each of the one or more second material layers 14-1 and 14-2. Each of the one or more second material layers 14-1 and 14-2 can include a piezoelectric material including a higher relative density and a higher dielectric constant than those of each of the one or more first material layers 11-1 to 11-3. For example, each of the one or more second material layers 14-1 and 14-2 can include a KNN-based piezoelectric material to which TGG is not applied. For example, the one or more second material layers 14-1 and 14-2 can be configured or implemented to complement the reduced relative density and dielectric constant of each of the one or more first material layers 11-1 to 11-3.

According to an embodiment of the present disclosure, the number of second material layers 14-1 and 14-2 can be equal to or different from the number of one or more first material layers 11-1 to 11-3. For example, the number of one or more first material layers 11-1 to 11-3 can be more than the number of second material layers 14-1 and 14-2. For example, the one or more first material layers 11-1 to 11-3 can include a 1-1 material layer 11-1, a 1-2 material layer 11-2, and a 1-3 material layer 11-3. The one or more second material layers 14-1 and 14-2 can include a 2-1 material layer 14-1 and a 2-2 material layer 14-2. Some of the one or more first material layers 11-1 to 11-3 can be disposed or provided between the one or more second material layers 14-1 and 14-2. For example, the 2-1 material layer 11-1 provided at a lowermost layer of the piezoelectric device layer 10 among the one or more first material layers 11-1 to 11-3 can be configured to contact or be connected with the first electrode layer 21. Also, the 1-3 material layer 11-3 provided at an uppermost layer of the piezoelectric device layer 10 among the one or more first material layers 11-1 to 11-3 can be configured to contact or be connected with the second electrode layer 22. The one or more second material layers 14-1 and 14-2 can be disposed between the 1-1 material layer 11-1 and the 1-3 material layer 11-3. Also, the other of the one or more first material layers 11 can be disposed between the 1-1 material layer 11-1 and the 1-3 material layer 11-3. For example, the 1-2 material layer 11-1 can be disposed between the 1-1 material layer 11-1 and the 1-3 material layer 11-3.

Each of the one or more first material layers 11-1 to 11-3 and the one or more second material layers 14-1 and 14-2 can be individually formed through a tape casting process. Each of the one or more first material layers 11-1 to 11-3 and the one or more second material layers 14-1 and 14-2 can be configured or implemented to be alternately stacked. For example, the 1-1 material layer 11-1 can be disposed at a first surface (or an upper surface) of the first electrode layer 21. The 2-1 material layer 14-1 can be disposed at a first surface (or an upper surface) of the 1-1 material layer 11-1. Also, the 1-1 material layer 11-1 can be disposed between the first electrode layer 21 and the 2-1 material layer 14-1. Also, the 1-2 material layer 11-2 can be disposed at a first surface (or an upper surface) of the 2-1 material layer 14-1. Also, the 2-1 material layer 14-1 can be disposed between the 1-1 material layer 11-1 and the 1-2 material layer 11-2. Also, the 2-2 material layer 14-2 can be disposed at a first surface (or an upper surface) of the 1-2 material layer 11-2. Also, the 1-2 material layer 11-2 can be disposed between the 2-1 material layer 14-1 and the 2-2 material layer 14-2. Also, the 1-3 material layer 11-3 can be disposed at a first surface (or an upper surface) of the 2-2 material layer 14-2. Also, the 2-2 material layer 14-2 can be disposed between the 1-2 material layer 11-2 and the 1-3 material layer 11-3. Also, the second electrode layer 22 can be disposed at a first surface (or an upper surface) of the 1-3 material layer 11-3. Also, the 1-3 material layer 11-3 can be disposed between the 2-2 material layer 14-2 and the second electrode layer 22.

According to another embodiment of the present disclosure, the one or more second material layers 14-1 and 14-2 can be configured between the one or more first material layers 11-1 to 11-3. For example, a KNN-based piezoelectric material to which TGG is not applied can be configured between KNN-based piezoelectric materials to which TGG is applied. For example, the one or more first material layers 11-1 and 11-3 can be configured at an outer portion of the piezoelectric device 2 with the one or more second material layers 14-1 and 14-2 therebetween. For example, the KNN-based piezoelectric material to which TGG is applied can be configured at the outer portion of the piezoelectric device 2 with the KNN-based piezoelectric material, to which TGG is not applied, therebetween. The KNN-based piezoelectric material to which TGG is applied can be configured at the outer portion (or upper and lower outer portion) of the piezoelectric device 2 with the KNN-based piezoelectric material, to which TGG is not applied, therebetween, and thus, can improve a vibration characteristic. For example, the KNN-based piezoelectric material to which TGG is applied can have an advantage where a piezoelectric constant increases to 650 pC/N to 800 pC/N, but due to a reduction in relative density and dielectric constant, vibration intensity can be weakened because a larger blocking force is applied than the KNN-based piezoelectric material to which TGG is not applied. Therefore, according to another embodiment of the present disclosure, in order to complement a reduction in vibration intensity of the KNN-based piezoelectric material to which TGG is applied, a thickness of the KNN-based piezoelectric material to which TGG is not applied can be configured to be higher than that of the KNN-based piezoelectric material to which TGG is applied.

Each of the one or more first material layers 11-1 to 11-3 can have a thickness which differs from that of each of at least one second material layers 14-1 and 14-2, or can have a thickness which is greater than or equal to that of each of the at least one second material layers 14-1 and 14-2.

According to an embodiment of the present disclosure, as illustrated in FIG. 6, each of the one or more first material layers 11-1 to 11-3 can be configured to have the first thickness T1, and each of the one or more second material layers 14-1 and 14-2 can be configured to have the second thickness T2. The first thickness T1 of each of the one or more first material layers 11-1 to 11-3 and the second thickness T2 of each of the one or more second material layers 14-1 and 14-2 can have the same height or different heights. For example, the first thickness T1 and the second thickness T2 can have substantially the same height within an error range of a manufacturing process.

According to another embodiment of the present disclosure, as illustrated in FIG. 7, each of the one or more first material layers 11-1 to 11-3 can be configured to have the third thickness T3, and each of the at least one second material layers 14-1 and 14-2 can be configured to have the second thickness T2. The third thickness T3 of each of the one or more first material layers 11-1 to 11-3 can have a height which is greater than the second thickness T2 of the at least one second material layers 14-1 and 14-2. For example, the one or more first material layers 11-1 to 11-3 can decrease in relative density and dielectric constant through TGG, and due to this, a blocking force which is greater than the one or more second material layers 14-1 and 14-2 can act thereon, whereby vibration intensity can be weakened. Accordingly, according to another embodiment of the present disclosure, in order to complement a reduction in vibration intensity of the one or more first material layers 11-1 to 11-3, a thickness of each of the one or more first material layers 11-1 to 11-3 can be configured to have a height which is 1.5 to 3 times a thickness of each of the one or more second material layers 14-1 and 14-2, but embodiments of the present disclosure are not limited thereto.

In the piezoelectric device 2 according to another embodiment of the present disclosure, except for that each of the one or more first material layers 11-1 to 11-3 includes the KNN-based piezoelectric material to which TGG is applied and each of the one or more second material layers 14-1 and 14-2 includes the KNN-based piezoelectric material to which TGG is not applied, a process of manufacturing the piezoelectric device layer 10 according to another embodiment of the present disclosure can be the same as the descriptions of FIG. 1, and thus, repeated descriptions thereof are omitted.

In the piezoelectric device 2 according to an embodiment of the present disclosure, the piezoelectric device layer 10 need not include Pb, and the reliability and driving characteristic of the piezoelectric device layer 10 or the piezoelectric device 2 can be enhanced or improved. Also, because the piezoelectric device layer 10 does not include Pb, a production restriction material can be reduced and replacement of a harmful material can be implemented, and thus, an environment-friendly piezoelectric device 2 and an apparatus including the same can be implemented or realized.

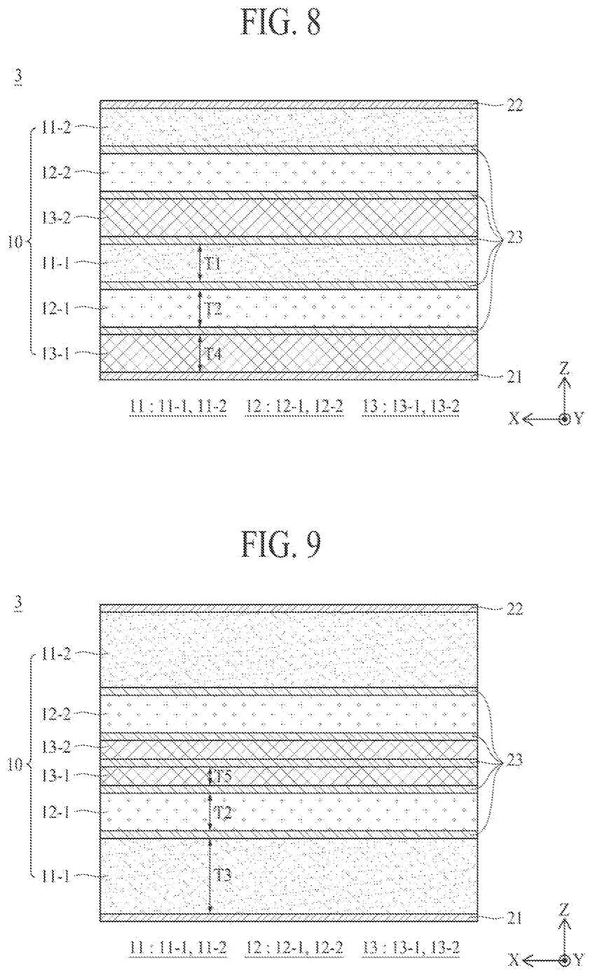

FIG. 8 illustrates a piezoelectric device according to another embodiment of the present disclosure. FIG. 9 illustrates another structure of a piezoelectric device according to another embodiment of the present disclosure. Particularly, FIGS. 8 and 9 illustrate an embodiment where a third vibration portion is additionally provided in the piezoelectric device layer 10 in the piezoelectric devices 1 described above with reference to FIGS. 1 to 5. In the following description, therefore, the same elements other than a configuration of a third vibration portion and relevant elements are referred to by like reference numerals, and repeated descriptions thereof are omitted or will be briefly given.

Referring to FIGS. 8 and 9, the piezoelectric device 3 according to another embodiment of the present disclosure can include a third vibration portion 13 having a characteristic which differs from that of each of a first vibration portion 11 and a second vibration portion 12 in a piezoelectric device layer 10.

Each of the first vibration portion 11, the second vibration portion 12, and the third vibration portion 13 of the piezoelectric device layer 10 can include a piezoelectric material having a piezoelectric effect (or a piezoelectric characteristic). For example, each of the first vibration portion 11, the second vibration portion 12, and the third vibration portion 13 can be an inorganic layer, an inorganic material layer, a piezoelectric material layer, an electro active layer, a piezoelectric portion, an inorganic portion, an inorganic material portion, a piezoelectric material portion, or an electro active portion, but embodiments of the present disclosure are not limited thereto.

The first vibration portion 11, the second vibration portion 12, and the third vibration portion 13 can include a ceramic-based material capable of implementing a relatively high vibration, or can include piezoelectric ceramic having a perovskite crystalline structure. The perovskite crystalline structure can have a piezoelectric and/or inverse piezoelectric effect and can be a plate-shaped structure having an orientation.

According to another embodiment of the present disclosure, each of the first vibration portion 11, the second vibration portion 12, and the third vibration portion 13 can include a lead zirconate titanate (PZT)-based piezoelectric material including Pb, zirconium (Zr), and titanium (Ti) each having a high piezoelectric characteristic, but is not limited thereto and can include a Pb-free piezoelectric material so as to prevent the toxicity of Pb and environmental pollution caused by a harmful material occurring in a sintering process. The first vibration portion 11, the second vibration portion 12, and the third vibration portion 13 according to an embodiment of the present disclosure can respectively include piezoelectric materials having different characteristics among Pb-free piezoelectric materials. For example, each of the first vibration portion 11, the second vibration portion 12, and the third vibration portion 13 can respectively include Pb-free piezoelectric materials having different characteristics.

The different characteristics of each of the first vibration portion 11, the second vibration portion 12, and the third vibration portion 13 can include one or more of a curie temperature (T_{C}), a piezoelectric constant (d₃₃), a coercive field (E_{C}), a relative density (%), a theoretical density or specific gravity, and a dielectric constant (ε).

Each of the first vibration portion 11, the second vibration portion 12, and the third vibration portion 13 according to another embodiment of the present disclosure can include one or more of different characteristics.

One of the first vibration portion 11, the second vibration portion 12, and the third vibration portion 13 can include one or more of a relative density of 90% or more and a curie temperature of 170° C. or more. For example, one of the first vibration portion 11, the second vibration portion 12, and the third vibration portion 13 can include a piezoelectric material including a relative density of 90% or more and a curie temperature of 170° C. or more. Also, the piezoelectric material including a relative density of 90% or more and a curie temperature of 170° C. or more can include a piezoelectric constant of 650 pC/N to 800 pC/N. For example, one of the first vibration portion 11, the second vibration portion 12, and the third vibration portion 13 can include a piezoelectric material including a relative density of 90% or more, a curie temperature of 170° C. or more, and a piezoelectric constant of 650 pC/N to 800 pC/N. For example, one of the first vibration portion 11, the second vibration portion 12, and the third vibration portion 13 can include a piezoelectric material including one or more of a relative density of 90% or more, a curie temperature of 170° C. or more, and a piezoelectric constant of 650 pC/N to 800 pC/N, and the other of the first vibration portion 11, the second vibration portion 12, and the third vibration portion 13 can include a piezoelectric material having a different characteristic.

One of the first vibration portion 11, the second vibration portion 12, and the third vibration portion 13 can include one or more of a relative density of 95% or more and a piezoelectric constant of 700 pC/N or more. For example, one of the first vibration portion 11, the second vibration portion 12, and the third vibration portion 13 can include a piezoelectric material including a relative density of 95% or more and a piezoelectric constant of 700 pC/N or more. For example, one of the first vibration portion 11, the second vibration portion 12, and the third vibration portion 13 can include a piezoelectric material including one or more of a relative density of 95% or more and a piezoelectric constant of 700 pC/N or more, and the other of the first vibration portion 11, the second vibration portion 12, and the third vibration portion 13 can include a piezoelectric material having a different characteristic.

One of the first vibration portion 11, the second vibration portion 12, and the third vibration portion 13 can include one or more of a coercive field of 10 kV/cm or more and a piezoelectric constant of 200 pC/N to 500 pC/N. For example, one of the first vibration portion 11, the second vibration portion 12, and the third vibration portion 13 can include a piezoelectric material including a coercive field of 10 kV/cm or more and a piezoelectric constant of 200 pC/N to 500 pC/N. For example, one of the first vibration portion 11, the second vibration portion 12, and the third vibration portion 13 can include a piezoelectric material including one or more of a coercive field of 10 kV/cm or more and a piezoelectric constant of 200 pC/N to 500 pC/N, and the other of the first vibration portion 11, the second vibration portion 12, and the third vibration portion 13 can include a piezoelectric material having a different characteristic.

The first vibration portion 11, the second vibration portion 12, and the third vibration portion 13 can include different materials of a KNN-based piezoelectric material including K, Na, and Nb, a BT-based piezoelectric material, and a Bi-based piezoelectric material. For example, the KNN-based piezoelectric material can include (K,Na)NbO₃, but embodiments of the present disclosure are not limited thereto. For example, the BT-based piezoelectric material can include (K,Na)NbO₃ or (Ba,Ca)TiO₃—Ba(Ti,Zr)O₃, but embodiments of the present disclosure are not limited thereto. For example, the Bi-based piezoelectric material can include at least one of (Na,Bi) TiO₃—BaTiO₃, BiFeO₃, Bi_{0.5}Na_{0.5}TiO₃(BNT), Bi(Na,K)TiO₃-BT-KNN, and (Bi,Na)TiO₃, but embodiments of the present disclosure are not limited thereto. Also, TGG can be applied to the KNN-based piezoelectric material, or can be not applied thereto. For example, one of the first vibration portion 11, the second vibration portion 12, and the third vibration portion 13 can include a KNN-based piezoelectric material to which TGG is applied, and the other of the first vibration portion 11, the second vibration portion 12, and the third vibration portion 13 can include a KNN-based piezoelectric material to which TGG is not applied, but embodiments of the present disclosure are not limited thereto. For example, the first vibration portion 11, the second vibration portion 12, and the third vibration portion 13 can be represented by Chemical Formula 1 or Chemical Formula 2.

Each of the first vibration portion 11, the second vibration portion 12, and the third vibration portion 13 of the piezoelectric device layer 10 according to an embodiment of the present disclosure can include one or more material layers. For example, the first vibration portion 11 can include one or more first material layers 11-1 and 11-2. The second vibration portion 12 can include one or more second material layers 12-1 and 12-2. The third vibration portion 13 can include one or more third material layers 13-1 and 13-2. The one or more first material layers 11-1 to 11-3, the one or more second material layers 12-1 and 12-2, and the one or more third material layers 13-1 and 13-2 can have different characteristics. For example, the one or more first material layers 11-1 to 11-3, the one or more second material layers 12-1 and 12-2, and the one or more third material layers 13-1 and 13-2 can include piezoelectric materials having different characteristics. For example, the one or more first material layers 11-1 to 11-3, the one or more second material layers 12-1 and 12-2, and the one or more third material layers 13-1 and 13-2 can include Pb-free piezoelectric materials. For example, the one or more first material layers 11-1 to 11-3, the one or more second material layers 12-1 and 12-2, and the one or more third material layers 13-1 and 13-2 can include Pb-free piezoelectric materials having different characteristics.

According to another embodiment of the present disclosure, each of the one or more first material layers 11-1 and 11-2 can include a piezoelectric material including one or more of a curie temperature which is higher than that of each of the one or more second material layers 12-1 and 12-2 and is lower than that of each of the one or more third material layers 13-1 and 13-2 and a piezoelectric constant which is less than that of each of the one or more second material layers 12-1 and 12-2 and is greater than that of each of the one or more third material layers 13-1 and 13-2. Also, each of the one or more third material layers 13-1 and 13-2 can include a piezoelectric material including a coercive field which is higher than that of each of the one or more first material layers 11-1 to 11-3 and the one or more second material layers 12-1 and 12-2.

Each of the one or more first material layers 11-1 and 11-2 can include one or more of a relative density of 90% or more and a curie temperature of 170° C. or more. For example, each of the one or more first material layers 11-1 and 11-2 can include a piezoelectric material including a relative density of 90% or more and a curie temperature of 170° C. or more. For example, each of the one or more first material layers 11-1 and 11-2 can include a KNN-based piezoelectric material including K, Na, and Nb. For example, the KNN-based piezoelectric material can include (K,Na)NbO₃, but embodiments of the present disclosure are not limited thereto. The one or more first material layers 11-1 and 11-2 can be configured or implemented to enhance or improve the reliability of the piezoelectric device layer 10 or the piezoelectric device 1. For example, the one or more first material layers 11-1 and 11-2 can be represented by Chemical Formula 1 or Chemical Formula 2.

Each of the one or more second material layers 12-1 and 12-2 can have one or more of a relative density of 95% or more and a piezoelectric constant of 700 pC/N or more. For example, each of the one or more second material layers 12-1 and 12-2 can include a piezoelectric material which has a relative density of 95% or more and a piezoelectric constant of 700 pC/N or more. For example, each of the one or more second material layers 12-1 and 12-2 can include a BT-based piezoelectric material. The BT-based piezoelectric material can include (Ba,Ca)TiO₃—Ba(Ti,Zr)O₃, but embodiments of the present disclosure are not limited thereto. The one or more second material layers 12-1 and 12-2 can be configured or implemented to enhance or improve a driving characteristic of the piezoelectric device layer 10 or the piezoelectric device 3.

Each of the one or more third material layers 13-1 and 13-2 can include one or more of a coercive field of 10 kV/cm or more and a piezoelectric constant of 200 pC/N to 500 pC/N. For example, each of the one or more third material layers 13-1 and 13-2 can include a piezoelectric material including a coercive field of 10 kV/cm or more and a piezoelectric constant of 200 pC/N to 500 pC/N. For example, each of the one or more third material layers 13-1 and 13-2 can include a Bi-based piezoelectric material. For example, the Bi-based piezoelectric material can include at least one of (Na,Bi)TiO₃—BaTiO₃, BiFeO₃, Bi_{0.5}Na_{0.5}TiO₃(BNT), Bi(Na,K)TiO₃-BT-KNN, and (Bi,Na)TiO₃, but embodiments of the present disclosure are not limited thereto. The one or more third material layers 13-1 and 13-2 can be configured to implement or realize a large strain characteristic of the piezoelectric device layer 10 or the piezoelectric device 3.

The number of one or more first material layers 11-1 to 11-3, the number of one or more second material layers 12-1 and 12-2, and the number of one or more third material layers 13-1 and 13-2 can be equal to or different from one another. For example, the number of one or more first material layers 11-1 to 11-3 can be equal to each of the number of one or more second material layers 12-1 and 12-2 and the number of one or more third material layers 13-1 and 13-2. For example, the one or more first material layers 11-1 to 11-3 can include a 1-1 material layer 11-1 and a 1-2 material layer 11-1. The one or more second material layers 12-1 and 12-2 can include a 2-1 material layer 12-1 and a 2-2 material layer 12-2. The one or more third material layers 13-1 and 13-2 can include a 3-1 material layer 13-1 and a 3-2 material layer 13-2.

According to another embodiment of the present disclosure, as illustrated in FIG. 8, the 3-1 material layer 13-1 provided at a lowermost layer of the piezoelectric device layer 10 among the one or more first material layers 11-1 and 11-2 can be configured to contact or be connected with the first electrode layer 21. Also, the 1-2 material layer 11-2 provided at an uppermost layer of the piezoelectric device layer 10 among the one or more first material layers 11-1 and 11-2 can be configured to contact or be connected with the second electrode layer 22. For example, the 3-1 material layer 13-1, the 2-1 material layer 12-1, and the 1-1 material layer 11-1 can be disposed to be sequentially stacked. Also, the 3-2 material layer 13-2, the 2-2 material layer 12-2, and the 1-2 material layer 11-2 can be disposed to be sequentially stacked.

According to another embodiment of the present disclosure, the one or more second material layers 12-1 and 12-2 can be configured between the one or more first material layers 11-1 and 11-2 and the one or more third material layers 13-1 and 13-2. For example, the BT-based piezoelectric material can be provided between the KNN-based piezoelectric material and the Bi-based piezoelectric material. For example, the one or more first material layers 11-2 can be provided more outward from the piezoelectric device 3 than the one or more second material layers 12-2. The KNN-based piezoelectric material can be provided more outward from the piezoelectric device 3 than the BT-based piezoelectric material. Because the KNN-based piezoelectric material is provided more outward from the piezoelectric device 3 than the BT-based piezoelectric material, the low thermal stability and low reliability of the BT-based piezoelectric material can be complemented. For example, the one or more third material layers 13-1 can be provided more outward from the piezoelectric device 3 than the one or more second material layers 12-1. The Bi-based piezoelectric material can be provided more outward from the piezoelectric device 3 than the BT-based piezoelectric material. Because the Bi-based piezoelectric material is provided more outward from the piezoelectric device 3 than the BT-based piezoelectric material, the low thermal stability and low reliability of the BT-based piezoelectric material can be complemented. According to another embodiment of the present disclosure, as illustrated in FIG. 9, the one or more second material layers 12-1 and 12-2 and the one or more third material layers 13-1 and 13-2 can be disposed between the one or more first material layers 11-1 and 11-2. For example, the 1-1 material layer 11-1 provided at a lowermost layer of the piezoelectric device layer 10 among the one or more first material layers 11-1 and 11-2 can be configured to contact or be connected with the first electrode layer 21. Also, the 1-2 material layer 11-2 provided at an uppermost layer of the piezoelectric device layer 10 among the one or more first material layers 11-1 and 11-2 can be configured to contact or be connected with the second electrode layer 22. For example, the one or more second material layers 12-1 and 12-2 and the one or more third material layers 13-1 and 13-2 can be disposed between the −1-1 material layer 11-1 and the 1-2 material layer 11-2. For example, the one or more third material layers 13-1 and 13-2 can be disposed at a center portion of the piezoelectric device layer 10. Also, the one or more third material layers 13-1 and 13-2 can be disposed between the 2-1 material layer 12-1 and the 2-2 material layer 12-2. Also, the one or more third material layers 13-1 and 13-2 and the one or more second material layers 12-1 and 12-2 can be disposed between the 1-1 material layer 11-1 and the 1-2 material layer 11-2.

According to another embodiment of the present disclosure, the one or more third material layers 13-1 and 13-2 can be configured between the one or more second material layers 12-1 and 12-2. For example, the Bi-based piezoelectric material can be provided between BT-based piezoelectric materials. For example, the one or more first material layers 11-1 and 11-2 can be provided more outward from the piezoelectric device 3 than the one or more second material layers 12-1 and 12-2. The KNN-based piezoelectric material can be provided more outward from the piezoelectric device 3 than the BT-based piezoelectric material. Because the KNN-based piezoelectric material is provided more outward from the piezoelectric device 3 than the BT-based piezoelectric material, a degradation in the piezoelectric device 3 caused by a low curie temperature of the BT-based piezoelectric material can be prevented, and thus, the reliability of the piezoelectric device 3 can be enhanced, thereby enhancing a vibration characteristic of the piezoelectric device 3 based on a high piezoelectric constant of the BT-based piezoelectric material. Each of the one or more first material layers 11-1 and 11-2 can have a thickness which differs from that of each of the one or more second material layers 12-1 and 12-2 and the one or more third material layers 13-1 and 13-2, or can have a thickness which is greater than or equal to that of each of the one or more second material layers 12-1 and 12-2 and the one or more third material layers 13-1 and 13-2.

According to another embodiment of the present disclosure, as illustrated in FIG. 8, each of the one or more first material layers 11-1 and 11-2 can be configured to have the first thickness T1, each of the one or more second material layers 12-1 and 12-2 can be configured to have the second thickness T2, and each of the one or more third material layers 13-1 and 13-2 can be configured to have a fourth thickness T4. The first thickness T1 of each of the one or more first material layers 11-1 and 11-2, the second thickness T2 of each of the one or more second material layers 12-1 and 12-2, and the fourth thickness T4 of each of the one or more third material layers 13-1 and 13-2 can have the same height or different heights. For example, the first thickness T1, the second thickness T2, and the fourth thickness T4 can have substantially the same height within an error range of a manufacturing process.

According to another embodiment of the present disclosure, as illustrated in FIG. 9, each of one or more first material layers 11-1 and 11-2 can be configured to have the third thickness T3, each of the one or more second material layers 12-1 and 12-2 can be configured to have the second thickness T2, and each of the one or more third material layers 13-1 and 13-2 can be configured to have a fifth thickness T5. The third thickness T3 of each of the one or more first material layers 11-1 and 11-2 can have a height which is greater than that of each of the second thickness T2 of each of the one or more second material layers 12-1 and 12-2 and the fifth thickness T5 of each of the one or more third material layers 13-1 and 13-2. Also, the second thickness T2 of each of the one or more second material layers 12-1 and 12-2 can have a height which is less than that of the third thickness T3 of each of the one or more first material layers 11-1 and 11-2 and is greater than that of the fifth thickness T5 of each of the one or more third material layers 13-1 and 13-2. Also, the fifth thickness T5 of each of the one or more third material layers 13-1 and 13-2 can have a height which is less than that of each of the third thickness T3 of each of the one or more first material layers 11-1 and 11-2 and the second thickness T2 of each of the one or more second material layers 12-1 and 12-2. Also, the KNN-based piezoelectric material included in the one or more first material layers 11-1 and 11-2 can have a density of 4.0 g/cm³ to 4.7 g/cm³, and the BT-based piezoelectric material included in one or more second material layers 12-1 to 12-4 can have a density of 5.7 g/cm³ to 6.0 g/cm³. Therefore, because the one or more first material layers 11-1 and 11-2 have a density which is relatively lower than that of each of the one or more second material layers 12-1 to 12-4, a blocking force which is greater than the one or more second material layers 12-1 to 12-4 can act thereon, and due to this, vibration intensity can be weakened. Accordingly, according to another embodiment of the present disclosure, in order to complement a reduction in vibration intensity of the one or more first material layers 11-1 and 11-2, a thickness of each of the one or more first material layers 11-1 and 11-2 can be adjusted to have a height which is 1.5 to 3 times a thickness of each of the one or more second material layers 12-1 to 12-4, but embodiments of the present disclosure are not limited thereto. The Bi-based piezoelectric material included in the one or more third material layers 13-1 and 13-2 has a large strain but is high in coercive field E_{C}, a thickness of each of the one or more third material layers 13-1 and 13-2 can be configured to have a height which is ½ times a thickness of each of the one or more second material layers 12-1 to 12-4, but embodiments of the present disclosure are not limited thereto.

In the piezoelectric device 3 according to another embodiment of the present disclosure, except for that the one or more third material layers 13-1 and 13-2 are additionally provided, a process of manufacturing the piezoelectric device layer 10 according to another embodiment of the present disclosure can be the same as the descriptions of FIG. 1, and thus, repeated descriptions thereof are omitted.

In the piezoelectric device 3 according to another embodiment of the present disclosure, the piezoelectric device layer 10 need not include Pb, and the reliability and driving characteristic of the piezoelectric device layer 10 or the piezoelectric device 3 can be enhanced or improved. Also, the piezoelectric device 3 according to another embodiment of the present disclosure can be implement or realize a large strain characteristic. Also, because the piezoelectric device layer 10 does not include Pb, a production restriction material can be reduced and replacement of a harmful material can be implemented, and thus, an environment-friendly piezoelectric device 3 and an apparatus including the same can be implemented or realized.

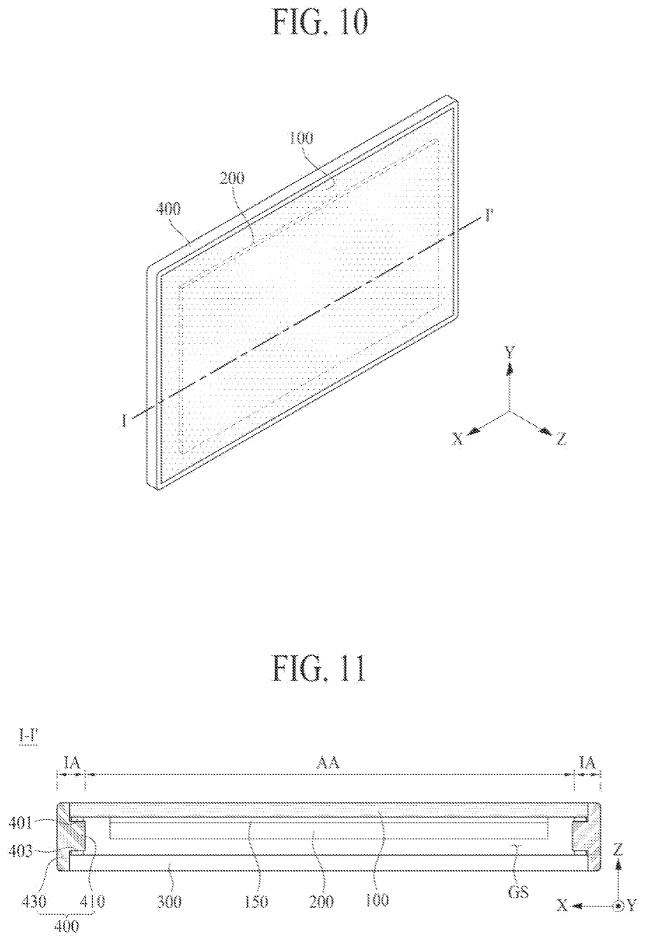

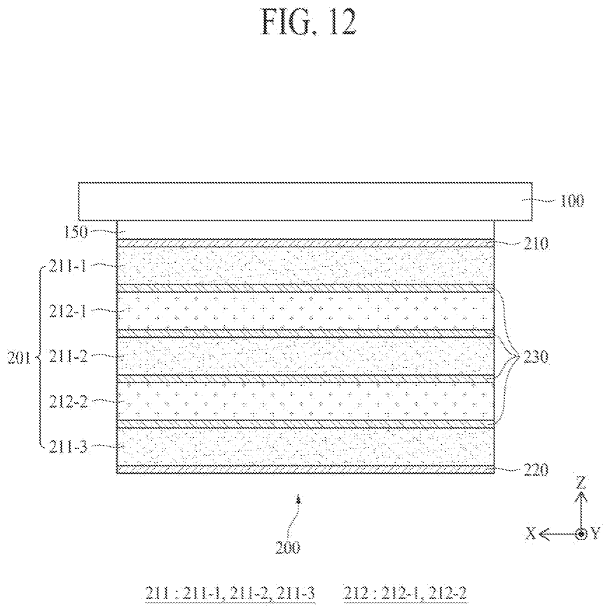

FIG. 10 illustrates an apparatus according to an embodiment of the present disclosure. FIG. 11 is a cross-sectional view taken along line I-I′ of FIG. 10 according to an embodiment of the present disclosure. FIG. 12 illustrates a vibration apparatus of FIG. 11 according to an embodiment of the present disclosure. All the components of each apparatus and each vibration apparatus according to all embodiments of the present disclosure are operatively coupled.

Referring to FIGS. 10 and 11, an apparatus according to an embodiment of the present disclosure can be implemented or provided as a sound apparatus, a sound output apparatus, a vibration apparatus, a vibration generating apparatus, a sound bar, a sound system, a sound apparatus for electronic apparatuses, a sound apparatus for display apparatuses, a sound apparatus for vehicular apparatus, or a sound bar for vehicular apparatus. For example, the vehicular apparatus or the transporting apparatus can include one or more of seat and one or more of window. For example, the vehicular apparatus or the transporting apparatus can include a vehicle, a train, a ship, or an aircraft, but embodiments of the present disclosure are not limited thereto. The apparatus 1 according to an embodiment of the present disclosure can be implemented or provided as a signage panel such as an analog signage or digital signage such as an advertisement signboard, a poster, and a guide board.

The apparatus according to an embodiment of the present disclosure can be a display apparatus which includes a plurality of pixels, but embodiments of the present disclosure are not limited thereto.

The display apparatus can include a display panel, including a plurality of pixels implementing a black and white, or color image, and a driver for driving the display panel. Each of the plurality of pixels can be a subpixel configuring one of a plurality of colors implementing a color image. An apparatus according to an embodiment of the present disclosure can include a notebook computer, a television (TV), a computer monitor, an equipment apparatus including a specific form of a vehicle or a vehicular or automotive apparatus, and a set device (or a set apparatus) or a set electronic apparatus such as a smartphone or an electronic pad, which are complete products (or final products) including a display panel such as a liquid crystal display panel or an organic light emitting display panel.

Referring to FIG. 10, the apparatus according to an embodiment of the present disclosure can include a vibration member 100 and a vibration apparatus 200.

The vibration member 100 can generate or output a vibration (or a sound wave), based on a displacement (or driving) of the vibration apparatus 200. The vibration member 100 can be a vibration object, a display member, a display panel, a signage panel, a passive vibration member, a passive vibration plate, a front member, a rear member, a vibration panel, a sound panel, a passive vibration panel, a sound output plate, a sound vibration plate, or an image screen, but embodiments of the present disclosure are not limited thereto.

The vibration member 100 can include one or more of a display panel including a pixel configured to display an image, a screen panel on which an image is to be projected from a display apparatus, a lighting panel, a signage panel, a vehicular interior material, a vehicular glass window, a vehicular exterior material, a ceiling material of a building, an interior material of a building, a glass window of a building, an interior material of an aircraft, and a glass window of an aircraft. For example, the vibration member 100 can include one or more materials among wood, plastic, glass, metal, cloth, fiber, paper, rubber, leather, carbon, and mirror.

Hereinafter, an example where the vibration member 100 is a display panel will be described.

The display panel 100 can display an image, and for example, can display an image (for example, an electronic image, a digital image, a still image, or a video image). For example, the display panel 100 can emit light to display an image. The display panel 100 can be a curved display panel or all types of display panels such as a liquid crystal display panel, an organic light emitting display panel, a quantum dot light emitting display panel, a micro light emitting diode display panel, and an electrophoresis display panel. The display panel 100 can be a flexible display panel. For example, the display panel 100 can be a flexible light emitting display panel, a flexible electrophoresis display panel, a flexible electro-wetting display panel, a flexible micro light emitting diode display panel, or a flexible quantum dot light emitting display panel, but embodiments of the present disclosure are not limited thereto.

The display panel 100 according to an embodiment of the present disclosure can include a display area AA which displays an image on the basis of driving of a plurality of pixels. Also, the display panel 100 can further include a non-display area IA which surrounds the display area AA, but embodiments of the present disclosure are not limited thereto.

The vibration apparatus 200 can be configured to vibrate the display panel 100. For example, the vibration apparatus 200 can vibrate the display panel 100 at a rear surface of the display panel 100, and thus, can provide a user with a sound and/or a haptic feedback on the basis of a vibration of the display panel 100. The vibration apparatus 200 can be implemented at the rear surface of the display panel 100 to directly vibrate the display panel 100.

According to an embodiment of the present disclosure, the vibration apparatus 200 can vibrate based on a vibration driving signal synchronized with an image displayed by the display panel 100, thereby vibrating the display panel 100. According to another embodiment of the present disclosure, the vibration apparatus 200 can vibrate based on a haptic feedback signal (or a tactile feedback signal) synchronized with a user touch applied to a touch panel (or a touch sensor layer) which is disposed on the display panel 100 or embedded in the display panel 100, and thus, can vibrate the display panel 100. Accordingly, the display panel 100 can vibrate based on a vibration of the vibration apparatus 200 to provide a user (or a viewer) with one or more of a sound and a haptic feedback.

The vibration apparatus 200 according to an embodiment of the present disclosure can be implemented to have a size corresponding to the display area AA of the display panel 100. A size of the vibration apparatus 200 can be 0.9 to 1.1 times a size of the display area AA of the display panel 100, but embodiments of the present disclosure are not limited thereto. For example, a size of the vibration apparatus 200 can be less than or equal to that of the display area AA. For example, a size of the vibration apparatus 200 can be equal to or almost equal to that of the display area AA of the display panel 100, and thus, can cover a large region of the display panel or the display panel 100 and a vibration generated by the vibration apparatus 200 can vibrate a whole region of the display panel 100, thereby enhancing satisfaction of a user and increasing a sense of orientation of a sound. Also, a contact area (or a panel coverage) between the display panel 100 and the vibration apparatus 200 can increase, and thus, a vibration region of the display panel 100 can increase, thereby enhancing a sound of a middle-low pitched sound band generated based on a vibration of the display panel 100. Also, the vibration apparatus 200 applied to a large-sized apparatus can vibrate all of the display panel 100 having a large size (or a large area), and thus, a sense of orientation of a sound based on a vibration of the display panel 100 can be more enhanced, thereby realizing an enhanced sound effect. Accordingly, the vibration apparatus 200 according to an embodiment of the present disclosure can be disposed at the rear surface of the display panel 100 to sufficiently vibrate the display panel 100 in a vertical (or forward and rearward) direction, thereby outputting a desired sound in a forward direction of the apparatus or the display apparatus.

The vibration apparatus 200 according to an embodiment of the present disclosure can be implemented as a film type. Because the vibration apparatus 200 is implemented as a film type, the vibration apparatus 200 can have a thickness which is thinner than the display panel 100, thereby minimizing an increase in thickness of the apparatus caused by the arrangement of the vibration apparatus 200. For example, the vibration apparatus 200 can be referred to as a sound generating module, a vibration generating apparatus, a film actuator, a film type piezoelectric composite actuator, a film speaker, a film type piezoelectric speaker, or a film type piezoelectric composite speaker, which uses the display panel 100 as a sound vibration plate, but embodiments of the present disclosure are not limited thereto.

In another embodiment of the present disclosure, the vibration apparatus 200 need not be disposed at the rear surface of the display panel 100 and can be applied to a vibration object instead of the display panel 100. For example, the vibration object can be a non-display panel, a mirror, an interior material of a vehicle, a glass window of a vehicle, an indoor ceiling of a building, a glass window of a building, an interior material of an aircraft, or a glass window of an aircraft, but embodiments of the present disclosure are not limited thereto. For example, the vibration object can be a sound panel or a sound plate including one or more materials of wood, metal, plastic, glass, cloth, paper, fiber, rubber, leather, and carbon, but embodiments of the present disclosure are not limited thereto. For example, the non-display panel can be a light emitting diode lighting panel (or apparatus), an organic light emitting lighting panel (or apparatus), or an inorganic light emitting lighting panel (or apparatus), but embodiments of the present disclosure are not limited thereto. In this case, a vibration object can be applied as a vibration plate, and the vibration apparatus 200 can vibrate the vibration object to output a sound.

Referring to FIG. 11, the apparatus according to an embodiment of the present disclosure can include a connection member 150 between the vibration apparatus 200 and the display panel 100.

The connection member 150 can include at least one base member and can include an adhesive layer attached on one surface or both surfaces of the base member, or can be configured as a single-layered adhesive layer.

According to an embodiment of the present disclosure, the connection member 150 can include a foam pad, a double-sided tape, a double-sided foam tape, or an adhesive, but embodiments of the present disclosure are not limited thereto. For example, the adhesive layer of the connection member 150 can include epoxy, acryl, silicone, or urethane, but embodiments of the present disclosure are not limited thereto.

The apparatus according to an embodiment of the present disclosure can further include a supporting member 300 which is disposed at the rear surface of the display panel 100.

The supporting member 300 can cover the rear surface of the display panel 100. For example, the supporting member 300 can cover the whole rear surface of the display panel 100 with a gap space GS therebetween. For example, the supporting member 300 can include one or more of a glass material, a metal material, and a plastic material. For example, the supporting member 300 can be a rear structure or a set structure. For example, the supporting member 300 can be referred to as the other term such as a cover bottom, a plate bottom, a back cover, a base frame, a metal frame, a metal chassis, a chassis base, or an m-chassis. Therefore, the supporting member 300 can be implemented as an arbitrary type frame or a plate structure disposed on the rear surface of the display panel 100.

The apparatus according to an embodiment of the present disclosure can further include a middle frame 400.

The middle frame 400 can be disposed between a rear edge of the display panel 100 and a front edge portion of the supporting member 300. The middle frame 400 can support each of one or more of an edge portion of the display panel 100 and an edge portion of the supporting member 300 and can surround one or more of lateral surfaces of each of the display panel 100 and the supporting member 300. The middle frame 400 can provide a gap space GS between the display panel 100 and the supporting member 300. The middle frame 400 can be referred to as a middle cabinet, a middle cover, or a middle chassis, but embodiments of the present disclosure are not limited thereto.

The middle frame 400 according to an embodiment of the present disclosure can include a first supporting portion 410 and a second supporting portion 430.

The first supporting portion 410 can be disposed between the rear edge of the display panel 100 and the front edge of the supporting member 300, and thus, can provide the gap space GS between the display panel 100 and the supporting member 300. A front surface of the first supporting portion 410 can be coupled to or connected with the rear edge portion of the display panel 100 by a first frame connection member 401. A rear surface of the first supporting portion 410 can be coupled to or connected with a front edge portion of the supporting member 300 by a second frame connection member 403. For example, the first supporting portion 410 can have a single picture frame structure having a tetragonal shape, or can include a picture frame structure having a plurality of division bar shapes.

The second supporting portion 430 can be vertically coupled to an outer surface of the first supporting portion 410 in parallel with a thickness direction Z of an apparatus. The second supporting portion 430 can surround one or more of an outer surface of the display panel 100 and an outer surface of the supporting member 300, and thus, can protect the outer surface of each of the display panel 100 and the supporting member 300. The first supporting portion 410 can protrude toward the gap space GS between the display panel 100 and the supporting member 300 from an inner surface of the second supporting portion 430.

Referring to FIG. 12, the vibration apparatus 200 according to an embodiment of the present disclosure can include a piezoelectric device layer 201. The piezoelectric device layer 201 can be the same as or substantially the same as the piezoelectric device layer 10 of the piezoelectric devices 1 to 3 described above with reference to FIGS. 1 to 9, and thus, repeated descriptions thereof are omitted or will be briefly given below.

The vibration apparatus 200 can include a piezoelectric device layer 201, a first electrode layer 210, a second electrode layer 220, and one or more middle electrode layers 230.

The piezoelectric device layer 201 can be configured between the first electrode layer 210 and the second electrode layer 220. The piezoelectric device layer 201 can include a first vibration portion 211 and a second vibration portion 212 having different characteristics. For example, the first vibration portion 211 and the second vibration portion 212 can be configured to overlap each other in a thickness direction Z of the piezoelectric device layer 201. The piezoelectric device layer 201 can include a circular plate shape, a polygonal plate shape, an oval shape, or a ring shape, but embodiments of the present disclosure are not limited thereto. For example, each of the first vibration portion 211 and the second vibration portion 212 each included in the piezoelectric device layer 201 can include a circular plate shape, a polygonal plate shape, an oval shape, or a ring shape, but embodiments of the present disclosure are not limited thereto.

Each of the first vibration portion 211 and the second vibration portion 212 of the piezoelectric device layer 201 can include a piezoelectric material having a piezoelectric effect (or a piezoelectric characteristic). For example, each of the first vibration portion 211 and the second vibration portion 212 can be an inorganic layer, an inorganic material layer, a piezoelectric material layer, an electro active layer, a piezoelectric portion, an inorganic portion, an inorganic material portion, a piezoelectric material portion, or an electro active portion, but embodiments of the present disclosure are not limited thereto.

The first vibration portion 211 and the second vibration portion 212 can include a ceramic-based material capable of implementing a relatively high vibration, or can include piezoelectric ceramic having a perovskite crystalline structure. The perovskite crystalline structure can have a piezoelectric and/or inverse piezoelectric effect and can be a plate-shaped structure having an orientation.

According to an embodiment of the present disclosure, each of the first vibration portion 211 and the second vibration portion 212 can include a lead zirconate titanate (PZT)-based piezoelectric material including Pb, zirconium (Zr), and titanium (Ti) each having a high piezoelectric characteristic, but is not limited thereto and can include a Pb-free piezoelectric material so as to prevent the toxicity of Pb and environmental pollution caused by a harmful material occurring in a sintering process. The first vibration portion 211 and the second vibration portion 212 according to an embodiment of the present disclosure can respectively include piezoelectric materials having different characteristics among Pb-free piezoelectric materials. For example, the first vibration portion 211 and the second vibration portion 212 can respectively include Pb-free piezoelectric materials having different characteristics.

The different characteristics of the first vibration portion 211 and the second vibration portion 212 can include one or more of a curie temperature (T_{C}), a piezoelectric constant (d₃₃), a coercive field (E_{C}), a relative density (%), a theoretical density or specific gravity, and a dielectric constant (ε).

The first vibration portion 211 and the second vibration portion 212 according to an embodiment of the present disclosure can include one or more of different characteristics.

One of the first vibration portion 211 and the second vibration portion 212 can include one or more of a relative density of 90% or more and a curie temperature of 170° C. or more. For example, one of the first vibration portion 211 and the second vibration portion 212 can include a piezoelectric material including a relative density of 90% or more and a curie temperature of 170° C. or more. Also, the piezoelectric material including a relative density of 90% or more and a curie temperature of 170° C. or more can include a piezoelectric constant of 650 pC/N to 800 pC/N. For example, one of the first vibration portion 211 and the second vibration portion 212 can include a piezoelectric material including a relative density of 90% or more, a curie temperature of 170° ° C. or more, and a piezoelectric constant of 650 pC/N to 800 pC/N. For example, one of the first vibration portion 211 and the second vibration portion 212 can include a piezoelectric material including one or more of a relative density of 90% or more, a curie temperature of 170° C. or more, and a piezoelectric constant of 650 pC/N to 800 pC/N, and the other of the first vibration portion 211 and the second vibration portion 212 can include a piezoelectric material having a different characteristic.

One of the first vibration portion 211 and the second vibration portion 212 can include one or more of a relative density of 95% or more and a piezoelectric constant of 700 pC/N or more. For example, one of the first vibration portion 211 and the second vibration portion 212 can include a piezoelectric material including a relative density of 95% or more and a piezoelectric constant of 700 pC/N or more. For example, one of the first vibration portion 211 and the second vibration portion 212 can include a piezoelectric material including one or more of a relative density of 95% or more and a piezoelectric constant of 700 pC/N or more, and the other of the first vibration portion 211 and the second vibration portion 212 can include a piezoelectric material having a different characteristic.

One of the first vibration portion 211 and the second vibration portion 212 can include one or more of a coercive field of 10 kV/cm or more and a piezoelectric constant of 200 pC/N to 500 pC/N. For example, one of the first vibration portion 211 and the second vibration portion 212 can include a piezoelectric material including a coercive field of 10 kV/cm or more and a piezoelectric constant of 200 pC/N to 500 pC/N. For example, one of the first vibration portion 211 and the second vibration portion 212 can include a piezoelectric material including one or more of a coercive field of 10 kV/cm or more and a piezoelectric constant of 200 pC/N to 500 pC/N, and the other of the first vibration portion 211 and the second vibration portion 212 can include a piezoelectric material having a different characteristic.

The first vibration portion 211 and the second vibration portion 212 can include different materials of a KNN-based piezoelectric material including K, Na, and Nb, a BT-based piezoelectric material, and a Bi-based piezoelectric material. For example, the KNN-based piezoelectric material can include (K,Na)NbO₃, but embodiments of the present disclosure are not limited thereto. For example, the BT-based piezoelectric material can include (K,Na)NbO₃ or (Ba,Ca)TiO₃—Ba(Ti,Zr)O₃, but embodiments of the present disclosure are not limited thereto. For example, the Bi-based piezoelectric material can include at least one of (Na,Bi)TiO₃—BaTiO₃, BiFeO₃, Bi_{0.5}Na_{0.5}TiO₃(BNT), Bi(Na,K)TiO₃-BT-KNN, and (Bi,Na)TiO₃, but embodiments of the present disclosure are not limited thereto. Also, TGG can be applied to the KNN-based piezoelectric material, or can be not applied thereto. For example, one of the first vibration portion 211 and the second vibration portion 212 can include a KNN-based piezoelectric material to which TGG is applied, and the other of the first vibration portion 211 and the second vibration portion 212 can include a KNN-based piezoelectric material to which TGG is not applied, but embodiments of the present disclosure are not limited thereto. For example, the first vibration portion 211 and the second vibration portion 212 can be represented by Chemical Formula 1 or Chemical Formula 2.

Each of the first vibration portion 211 and the second vibration portion 212 of the piezoelectric device layer 201 according to an embodiment of the present disclosure can include one or more material layers. For example, the first vibration portion 211 can include one or more first material layers 211-1 to 211-3. The second vibration portion 212 can include one or more second material layers 212-1 and 212-2. The one or more first material layers 211-1 to 211-3 and the one or more second material layers 212-1 and 212-2 can have different characteristics. For example, the one or more first material layers 211-1 to 211-3 and the one or more second material layers 212-1 and 212-2 can include piezoelectric materials having different characteristics. For example, the one or more first material layers 211-1 to 211-3 and the one or more second material layers 212-1 and 212-2 can include Pb-free piezoelectric materials. For example, the one or more first material layers 211-1 to 211-3 and the one or more second material layers 212-1 and 212-2 can include Pb-free piezoelectric materials having different characteristics.

The first electrode layer 210 and the second electrode layer 220 can be provided to face each other with the piezoelectric device layer 201 therebetween.

Moreover, the piezoelectric device layer 201 can be disposed or interposed between adjacent material layers among one or more first material layers 211-1 to 211-3 and one or more second material layers 212-1 and 212-2, in the piezoelectric device layer 201. The one or more middle electrode layers 230 can have the same size as that of the piezoelectric device layer 201, or can have a size which is less than that of the piezoelectric device layer 201.

The one or more first material layers 211-1 to 211-3 of a first vibration portion 211 and the one or more second material layers 212-1 and 212-2 of a second vibration portion 212 can be individually formed through a tape casting process. Each of the one or more first material layers 211-1 to 211-3 and the one or more second material layers 212-1 and 212-2 can be configured or implemented to be alternately stacked with the one or more middle electrode layers 230 therebetween.

In the apparatus according to an embodiment of the present disclosure, the piezoelectric device layer 201 of the vibration apparatus 200 need not include Pb, and the reliability and driving characteristic of the piezoelectric device layer 201 or the vibration apparatus 200 can be enhanced or improved. Also, because the piezoelectric device layer 201 does not include Pb, a production restriction material can be reduced and replacement of a harmful material can be implemented, and thus, an environment-friendly vibration apparatus 200 and an apparatus including the same can be implemented or realized.

A piezoelectric device and an apparatus including the same according to various embodiments of the present disclosure will be described below.

A piezoelectric device according to various embodiments of the present disclosure can include a piezoelectric device layer, a first electrode layer at a first surface of the piezoelectric device layer, and a second electrode layer at a second surface different from the first surface of the piezoelectric device layer. The piezoelectric device layer can include a first vibration portion and a second vibration portion overlapping each other in a thickness direction of the piezoelectric device layer and having different characteristics.

According to various embodiments of the present disclosure, the different characteristics can include one or more of a curie temperature (T_{C}), a piezoelectric constant (d₃₃), a coercive field (E_{C}), a relative density (%), a theoretical density or specific gravity, and a dielectric constant (ε).

According to various embodiments of the present disclosure, one of the first vibration portion and the second vibration portion can include one or more of a relative density of 90% or more and a curie temperature of 170° C. or more.

According to various embodiments of the present disclosure, the one of the first vibration portion and the second vibration portion can include a piezoelectric constant of 650 pC/N to 800 pC/N.

According to various embodiments of the present disclosure, one of the first vibration portion and the second vibration portion can include one or more of a relative density of 95% or more and a piezoelectric constant of 700 pC/N or more.

According to various embodiments of the present disclosure, one of the first vibration portion and the second vibration portion can include one or more of a coercive field of 10 kV/cm or more and a piezoelectric constant of 200 pC/N to 500 pC/N.

According to various embodiments of the present disclosure, the first vibration portion and the second vibration portion can include different materials of a potassium sodium niobate (KNN)-based material, a barium titanate (BT)-based material, and a bismuth (Bi)-based material.

According to various embodiments of the present disclosure, the piezoelectric device layer can further include one or more middle electrode layers disposed between the first vibration portion and the second vibration portion.

According to various embodiments of the present disclosure, the first vibration portion can include at least one first material layer. The second vibration portion can include at least one second material layer having a characteristic which differs from a characteristic of the at least one first material layer.

According to various embodiments of the present disclosure, the at least one first material layer can have a thickness which differs from a thickness of the at least one second material layer, or can have a thickness which is greater than or equal to a thickness of the at least one second material layer.

According to various embodiments of the present disclosure, one of the at least one first material layer can contact the first electrode layer. The other one of the at least one first material layers can contact the second electrode layer. The at least one second material layer can be between the first material layer contacting the first electrode layer and the first material layer contacting the second electrode layer.

According to various embodiments of the present disclosure, the other one of the at least one first material layer can be between the first material layer contacting the first electrode layer and the first material layer contacting the second electrode layer.

According to various embodiments of the present disclosure, the at least one second material layer includes at least two second material layers, and the at least one first material layer can be disposed between the at least two second material layers.

According to various embodiments of the present disclosure, the at least one first material layer can include includes at least two first material layers that can be adjacent to each other.

According to various embodiments of the present disclosure, the at least one second material layer includes at least two second material layers that can be adjacent to each other.

According to various embodiments of the present disclosure, a number of at least one first material layer can be equal to or different from a number of at least one second material layer.

According to various embodiments of the present disclosure, each of the at least one first material layer can include one or more of a higher curie temperature and a less piezoelectric constant than each of the at least one second material layer.

According to various embodiments of the present disclosure, each of the at least one first material layers can include a potassium sodium niobate (KNN)-based material. Each of the at least one second material layer can include a barium titanate (BT)-based material.

According to various embodiments of the present disclosure, each of the at least one first material layer can further include an additive added to the KNN-based material. The additive can include one or more of CuO, Fe₂O₃, La₂O₃, ZrO₂, ZnO, SnO₂, CdO, MnO₂, CuNb₂O₆, Gd₂O₃, Al₂O₃, CaO, BaO, HfO, TiO₂, Co₂O₃, NiO, MgO, B₂O₃, and SiO₂.

According to various embodiments of the present disclosure, each of the at least one second material layer can further include one or more of a first additive and one or more of a second additive each added to the BT-based material. The first additive can include one or more of CuO, Fe₂O₃, La₂O₃, ZrO₂, ZnO, SnO₂, CdO, MnO₂, CuNb₂O₆, Gd₂O₃, Al₂O₃, CaO, BaO, HfO, TiO₂, Co₂O₃, NiO, MgO, B₂O₃, and SiO₂. The second additive can include one or more of CaCl₂, AlF₃, BaCl₂, LiF, MgF₂, CaF₂, NaF, KF, NaCl, MgCl₂, KCl, ZnCl₂, LiCl₂, AlCl₃, CaSO₄, CaSO₃, Na₂SO₄, Na₂SO₃, and Na₂S.

According to various embodiments of the present disclosure, each of the at least one first material layer can include one or more of a higher piezoelectric constant, a lower curie temperature, and a lower relative density than each of the at least one second material layer.

According to various embodiments of the present disclosure, each of the at least one first material layer can include a potassium sodium niobate (KNN)-based material to which a templated grain growth (TGG) process is applied. Each of the at least one second material layers can include a KNN-based material to which the TGG process is not applied.

According to various embodiments of the present disclosure, the piezoelectric device layer can further include a third vibration portion having a characteristic which differs from a characteristic of each of the first vibration portion and the second vibration portion.

According to various embodiments of the present disclosure, the first vibration portion can include at least one first material layer. The second vibration portion can include at least one second material layer having a characteristic which differs from a characteristic of the at least one first material layer. The third vibration portion can include at least one third material layer having a characteristic which differs from a characteristic of each of the at least one first material layer and the at least one second material layer.

According to various embodiments of the present disclosure, each of the at least one first material layer can have a thickness which differs from a thickness of each of the at least one second material layer and the at least one third material layer, or can have a thickness which is greater than or equal to a thickness of each of the at least one second material layer and the at least one third material layer.

According to various embodiments of the present disclosure, each of the at least one third material layer can have a thickness which is less than a thickness of each of the at least one first material layer and the at least one second material layer.

According to various embodiments of the present disclosure, one of the at least one third material layer can contact the first electrode layer, one of the at least one first material layer can contact the second electrode layer, and the at least one second material layer can be between the at least one third material layer contacting the first electrode layer and the at least one first material layer contacting the second electrode layer.

According to various embodiments of the present disclosure, one or more of the other of the at least one first material layer and the other of the at least one third material layer can be between the third material layer contacting the first electrode layer and the first material layer contacting the second electrode layer.

According to various embodiments of the present disclosure, one of the at least one first material layer can include two first material layers, a first of the two first material layer can contact the first electrode layer, a second of the two first material layer can contact the second electrode layer, and the at least one second material layer and the at least one third material layer can be between the first of the two first material layers contacting the first electrode layer and the second of the two first material layers contacting the second electrode layer.

According to various embodiments of the present disclosure, the second of the two first material layers can be between the at least one third material layer and the second electrode layer.

According to various embodiments of the present disclosure, the at least one third material layer can be at a center of the piezoelectric device layer between the first electrode layer and the second electrode layer.

According to various embodiments of the present disclosure, when the at least one third material layer is disposed at the center of the piezoelectric device layer, the at least one third material layer can be between the two second material layers.

According to various embodiments of the present disclosure, when the at least one third material layer is provided, the at least two or more third material layers can be adjacent to each other.

According to various embodiments of the present disclosure, a number of at least one first material layer can be equal to or different from each of a number of at least one second material layer and a number of at least one third material layer.

According to various embodiments of the present disclosure, each of the at least one first material layer can include one or more of a curie temperature which is higher than each of the at least one second material layer and is lower than each of the at least one third material layer and a piezoelectric constant which is less than each of the at least one second material layer and is greater than each of the at least one third material layer. Each of the at least one third material layer can include a coercive field which is higher than each of the at least one first material layer and the at least one second material layer.

According to various embodiments of the present disclosure, each of the at least one first material layer can include a potassium sodium niobate (KNN)-based material. Each of the at least one second material layer can include a barium titanate (BT)-based material. Each of the at least one third material layer can include a bismuth (Bi)-based material.

An apparatus according to various embodiments of the present disclosure can include a vibration member, and at least one vibration apparatus configured to vibrate the vibration member, the at least one vibration apparatus can include a piezoelectric device layer, a first electrode layer at a first surface of the piezoelectric device layer, and a second electrode layer at a second surface different from the first surface of the piezoelectric device layer. The piezoelectric device layer can include a first vibration portion and a second vibration portion overlapping each other in a thickness direction of the piezoelectric device layer and having different characteristics.

According to various embodiments of the present disclosure, the vibration member can include one or more of a display panel including a plurality of pixels configured to display an image, a screen panel on which an image is to be projected from a display apparatus, a light emitting diode illumination panel, an organic light emitting illumination panel, an inorganic light emitting illumination panel, a signage panel, a vehicular interior material, a vehicular exterior material, a vehicular glass window, an interior material of a vehicular seat, a ceiling material of a building, an interior material of a building, a window of a building, an interior material of an aircraft, a glass window of an aircraft, and a mirror, or the vibration member can include one or more materials among metal, plastic, fiber, leather, wood, cloth, rubber, carbon, glass, mirror, and paper.

An apparatus according to an embodiment of the present disclosure can be applied to or included in a sound apparatus provided in the apparatus. The apparatus according to an embodiment of the present disclosure can be applied to or included in mobile apparatuses, video phones, smart watches, watch phones, wearable apparatuses, foldable apparatuses, rollable apparatuses, bendable apparatuses, flexible apparatuses, curved apparatuses, sliding apparatus, variable apparatus, electronic organizers, electronic book, portable multimedia players (PMPs), personal digital assistants (PDAs), MP3 players, mobile medical apparatuses, desktop personal computers (PCs), laptop PCs, netbook computers, workstations, navigation apparatuses, automotive navigation apparatuses, automotive display apparatuses, automotive apparatuses, theatrical apparatuses, theatrical display apparatuses, televisions (TVs), wall paper display apparatuses, signage apparatuses, game machines, notebook computers, monitors, cameras, camcorders, home appliances, etc. Also, the sound apparatus according to embodiments of the present disclosure can be applied to or included in organic light emitting lighting apparatuses or inorganic light emitting lighting apparatuses. In a case where the sound apparatus is applied to or included in a lighting apparatus, the sound apparatus can act as lighting and a speaker. Also, in a case where the sound apparatus according to embodiment of the present disclosure is applied to or included in a mobile apparatus, the sound apparatus can be one or more of a speaker, a receiver, or a haptic, but embodiments of the present disclosure are not limited thereto.

It will be apparent to those skilled in the art that various modifications and variations can be made in the present disclosure without departing from the scope of the present disclosure. Thus, it is intended that the present disclosure covers the modifications and variations of this disclosure provided they come within the scope of the appended claims and their equivalents.

What is claimed is:

1. A piezoelectric device comprising:
a piezoelectric device layer;
a first electrode layer at a first surface of the piezoelectric device layer; and
a second electrode layer at a second surface different from the first surface of the piezoelectric device layer,
wherein the piezoelectric device layer comprises a first vibration portion and a second vibration portion overlapping each other in a thickness direction of the piezoelectric device layer, and
wherein the first and second vibration portions have different characteristics.

2. The piezoelectric device of claim 1, wherein the different characteristics comprise one or more of a curie temperature (T_{C}), a piezoelectric constant (d₃₃), a coercive field (E_{C}), a relative density (%), a theoretical density or specific gravity, and a dielectric constant (ε).

3. The piezoelectric device of claim 1, wherein one of the first vibration portion and the second vibration portion comprises one or more of a relative density of about 90% or more and a curie temperature of about 170° C. or more.

4. The piezoelectric device of claim 3, wherein the one of the first vibration portion and the second vibration portion comprises a piezoelectric constant of about 650 pC/N to about 800 pC/N.

5. The piezoelectric device of claim 1, wherein one of the first vibration portion and the second vibration portion comprises one or more of a relative density of about 95% or more and a piezoelectric constant of about 700 pC/N or more.

6. The piezoelectric device of claim 1, wherein one of the first vibration portion and the second vibration portion comprises one or more of a coercive field of about 10 kV/cm or more and a piezoelectric constant of about 200 pC/N to about 500 pC/N.

7. The piezoelectric device of claim 1, wherein the first vibration portion and the second vibration portion comprise different materials of a potassium sodium niobate (KNN)-based material, a barium titanate (BT)-based material, and a bismuth (Bi)-based material.

8. The piezoelectric device of claim 1, wherein the piezoelectric device layer further comprises one or more middle electrode layers disposed between the first vibration portion and the second vibration portion.

9. The piezoelectric device of claim 1, wherein the first vibration portion comprises at least one first material layer, and
wherein the second vibration portion comprises at least one second material layer having a characteristic which differs from a characteristic of the at least one first material layer.

10. The piezoelectric device of claim 9, wherein the at least one first material layer has a thickness which differs from a thickness of the at least one second material layer, or has a thickness which is greater than or equal to a thickness of the at least one second material layer, or one of the at least one first material layer contacts the first electrode layer, the other one of the at least one first material layer contacts the second electrode layer, the at least one second material layer between the first material layer contacting the first electrode layer and the first material layer contacting the second electrode layer, and the other one of the at least one first material layer is between the first material layer contacting the first electrode layer and the first material layer contacting the second electrode layer.

11. The piezoelectric device of claim 9, wherein the at least one second material layer includes at least two second material layers, and the at least one first material layer is disposed between the at least two second material layers.

12. The piezoelectric device of claim 9, wherein the at least one first material layer includes at least two first material layers that are adjacent to each other, or the at least one second material layer includes at least two second material layers that are adjacent to each other.

13. The piezoelectric device of claim 9, wherein a number of at least one first material layer is equal to or different from a number of at least one second material layer.

14. The piezoelectric device of claim 9, wherein each of the at least one first material layer comprises one or more of a higher curie temperature and a less piezoelectric constant than each of the at least one second material layer.

15. The piezoelectric device of claim 14, wherein each of the at least one first material layer comprises a potassium sodium niobate (KNN)-based material, and
wherein each of the at least one second material layer comprises a barium titanate (BT)-based material.

16. The piezoelectric device of claim 15, wherein each of the at least one first material layer further comprises a first additive added to the KNN-based material,
wherein the first additive comprises one or more of CuO, Fe₂O₃, La₂O₃, ZrO₂, ZnO, SnO₂, CdO, MnO₂, CuNb₂O₆, Gd₂O₃, Al₂O₃, CaO, BaO, HfO, TiO₂, Co₂O₃, NiO, MgO, B₂O₃, and SiO₂,
wherein each of the at least one second material layer further comprises one or more of the first additive and one or more of a second additive each added to the BT-based material, and
wherein the second additive comprises one or more of CaCl₂, AlF₃, BaCl₂, LiF, MgF₂, CaF₂, NaF, KF, NaCl, MgCl₂, KCl, ZnCl₂, LiCl₂, AlCl₃, CaSO₄, CaSO₃, Na₂SO₄, Na₂SO₃, and Na₂S.

17. The piezoelectric device of claim 9, wherein each of the at least one first material layer comprises one or more of a higher piezoelectric constant, a lower curie temperature, and a lower relative density than each of the at least one second material layer.

18. The piezoelectric device of claim 17, wherein each of the at least one first material layer comprises a potassium sodium niobate (KNN)-based material to which a templated grain growth (TGG) process is applied, and
wherein each of the at least one second material layer comprises a KNN-based material to which the TGG process is not applied.

19. The piezoelectric device of claim 1, wherein the piezoelectric device layer further comprises a third vibration portion having a characteristic which differs from a characteristic of each of the first vibration portion and the second vibration portion.

20. The piezoelectric device of claim 19, wherein the first vibration portion comprises at least one first material layer,
wherein the second vibration portion comprises at least one second material layer having a characteristic which differs from a characteristic of the at least one first material layer, and
wherein the third vibration portion comprises at least one third material layer having a characteristic which differs from a characteristic of each of the at least one first material layer and the at least one second material layer.

21. The piezoelectric device of claim 20, wherein each of the at least one first material layer has a thickness which differs from a thickness of each of the at least one second material layer and the at least one third material layer, or has a thickness which is greater than or equal to a thickness of each of the at least one second material layer and the at least one third material layer, or
wherein each of the at least one third material layer has a thickness which is less than a thickness of each of the at least one first material layer and the at least one second material layer.

22. The piezoelectric device of claim 20, wherein one of the at least one third material layer contacts the first electrode layer, one of the at least one first material layer contacts the second electrode layer, and the at least one second material layer is between the at least one third material layer contacting the first electrode layer and the at least one first material layer contacting the second electrode layer.

23. The piezoelectric device of claim 20, wherein one of the at least one first material layer includes two first material layers, a first of the two first material layer contacts the first electrode layer, a second of the two first material layers contacts the second electrode layer, and the at least one second material layer and the at least one third material layer are disposed between the first of the two first material layers contacting the first electrode layer and the second of the two first material layers contacting the second electrode layer.

24. The piezoelectric device of claim 23, wherein the second of the two first material layers is disposed between the at least one third material layer and the second electrode, or
wherein the at least one third material layer is disposed at a center of the piezoelectric device layer between the first electrode layer and the second electrode layer.

25. The piezoelectric device of claim 24, wherein, when the at least one third material layer is disposed at the center of the piezoelectric device layer, the at least one third material layer is disposed between two second material layers, or
wherein, when at least one third material layer is provided, the at least two or more third material layers are adjacent to each other.

26. The piezoelectric device of claim 20, wherein a number of at least one first material layer is equal to or different from each of a number of at least one second material layer and a number of at least one third material layer.

27. The piezoelectric device of claim 20, wherein each of the at least one first material layer comprises one or more of a curie temperature which is higher than each of the at least one second material layer and is lower than each of the at least one third material layer and a piezoelectric constant which is less than each of the at least one second material layer and is greater than each of the at least one third material layer, and
wherein each of the at least one third material layer comprises a coercive field which is higher than each of the at least one first material layer and the at least one second material layer.

28. The piezoelectric device of claim 27, wherein each of the at least one first material layer comprises a potassium sodium niobate (KNN)-based material,
wherein each of the at least one second material layer comprises a barium titanate (BT)-based material, and
wherein each of the at least one third material layer comprises a bismuth (Bi)-based material.

29. An apparatus, comprising:
a vibration member; and
at least one vibration apparatus configured to vibrate the vibration member,
wherein the at least one vibration apparatus comprises the piezoelectric device of claim 1.

30. The apparatus of claim 29, wherein the vibration member comprises one or more of a display panel including a plurality of pixels configured to display an image, a screen panel on which an image is to be projected from a display apparatus, a light emitting diode illumination panel, an organic light emitting illumination panel, an inorganic light emitting illumination panel, a signage panel, a vehicular interior material, a vehicular exterior material, a vehicular glass window, an interior material of a vehicular seat, a ceiling material of a building, an interior material of a building, a window of a building, an interior material of an aircraft, a glass window of an aircraft, and a mirror, or
wherein the vibration member comprises one or more materials among metal, plastic, fiber, leather, wood, cloth, rubber, carbon, glass, mirror, and paper.
